(19) United States
(12) Patent Application Publication
(10) Pub. No.: US 2015/0001641 A1
(43) Pub. Date: Jan. 1, 2015

(54) TRANSISTOR AND SEMICONDUCTOR DEVICE

(71) Applicant: SAMSUNG ELECTRONICS CO., LTD., Suwon-si (KR)

(72) Inventors: Jae-Hyun YOO, Hwaseong-si (KR); Young-Keun LEE, Anyang-si (KR); Wook LEE, Suwon-si (KR); Jong-Sung JEON, Hwaseong-si (KR)

(73) Assignee: SAMSUNG ELECTRONICS CO., LTD., Suwon-si (KR)

(21) Appl. No.: 14/282,230

(22) Filed: May 20, 2014

(30) Foreign Application Priority Data
Jun. 26, 2013 (KR) 10-2013-0074038

(51) Int. Cl. H01L 29/78

(52) U.S. Cl. CPC H01L 29/78
USPC 257/402

(57) ABSTRACT

A transistor and a semiconductor device, the semiconductor device including an active region; a gate electrode on the active region; and a gate dielectric between the gate electrode and the active region, wherein the active region includes a first part overlapped by the gate electrode, and second and third parts facing each other with the first part therebetween, the first part of the active region includes a first portion having a first width and a second portion having a second width, the second width being greater than the first width, and the second portion of the active region is closer to the second part of the active region than to the third part of the active region.

### CROSS-REFERENCE TO RELATED APPLICATION

Korean Patent Application No. 10-2013-0074038, filed on Jun. 26, 2013, in the Korean Intellectual Property Office, and entitled: “Transistor and Semiconductor Device,” is incorporated by reference herein in its entirety.

### BACKGROUND

1. Field

Embodiments relate to a transistor and a semiconductor device.

2. Description of Related Art

As semiconductor devices become highly integrated, channel lengths and channel widths of transistors gradually decrease.

### SUMMARY

Embodiments are directed to a transistor and a semiconductor device.

The embodiments may be realized by providing a semiconductor device including an active region; a gate electrode on the active region; and a gate dielectric between the gate electrode and the active region, wherein the active region includes a first part overlapped by the gate electrode, and second and third parts facing each other with the first part therebetween, the first part of the active region includes a first portion having a first width and a second portion having a second width, the second width being greater than the first width, and the second portion of the active region is closer to the second part of the active region than to the third part of the active region.

The second portion of the active region may be continuously connected to the second part of the active region.

The second part of the active region may include a portion having the same width as the second portion of the active region.

The first width of the first portion of the active region and the second width of the second portion of the active region may be each defined by distances between two opposite first and second side surfaces of the active region, and the gate electrode may overlie the first and second side surfaces of the active region.

The first portion of the active region may be continuously connected to the third part of the active region.

The third part of the active region may include a portion having the same width as the first portion of the active region.

The first part of the active region may further include a third portion facing the second portion of the active region, the first portion of the active region being interposed between the second portion and the third portion, and the third portion of the active region may have a third width, the third width being greater than the first width.

One of the second and third parts of the active region may have the same width as the second portion of the active region at a portion thereof that is in contact with the first part, and a smaller width than the second portion of the active region at a portion thereof that is spaced apart from the first part of the active region.

The gate electrode may surround upper and side surfaces of the first part of the active region.

The embodiments may be realized by providing a transistor including an active region, the active region including a first part, a second part, and a third part, the second part and the third part facing each other with the first part interposed therebetween; a gate electrode overlapping the first part of the active region; a gate dielectric between the gate electrode and the active region; a drain region in the second part of the active region; a source region in the third part of the active region; and a channel region in the first part of the active region, wherein the channel region includes a first channel region and a second channel region, the second channel region having a channel width greater than the first channel region, and the second channel region is closer to the drain region than the first channel region.

The source region may have a shallower junction structure than the drain region.

The drain region may include a first drain region and a second drain region, the second drain region having side and bottom surfaces surrounded by the first drain region, and the second drain region may have a higher impurity concentration than the first drain region.

The transistor may further include an isolation region between the first part and the second part of the active region, wherein the first drain region surrounds side and bottom surfaces of the isolation region, and extends into a portion of the first part of the active region.

The transistor may further include a channel impurity area, the channel impurity area surrounding side and bottom surfaces of the source region, and being spaced apart from the drain region.

The transistor may further include an isolation region, the isolation region including a portion interposed between the first part and the second part of the active region, and a portion interposed between the first part and the third part of the active region, wherein the drain region surrounds side and bottom surfaces of the isolation region that are located between the first part and the second part of the active region, and extends into a portion of the first part of the active region, and wherein the source region surrounds side and bottom surfaces of the isolation region located between the first part and the third part of the active region, and extends into a portion of the first part of the active region.

The embodiments may be realized by providing a semiconductor device including an active region; a gate electrode on the active region; and a gate dielectric between the gate electrode and the active region, wherein the active region includes a first part overlapped by the gate electrode, a second part at one side of the first part, and a third part at another side of the first part such that the first part is between the second part and the third part, and the first part of the active region has a stepped shape including at least one discontinuous change in width therein.

The second part of the active region may include a portion having a same width as one portion of the first part of the active region.

The third part of the active region may include a portion having the same width as another portion of the first part of the active region.

At least one of the second part or the third part may have a stepped shape including at least one discontinuous change in width therein.

The gate electrode may surround upper and side surfaces of the first part of the active region.

### BRIEF DESCRIPTION OF THE DRAWINGS

Features will be apparent to those of skill in the art by describing in detail exemplary embodiments with reference to the attached drawings in which:

FIGS. 1A, 1B, 2A, 2B illustrate diagrams showing a semiconductor device in accordance with an embodiment;

FIGS. 3A, 3B, 4A, and 4B illustrate diagrams showing a semiconductor device in accordance with another embodiment;

FIGS. 5, 6A, and 6B illustrate diagrams showing a semiconductor device in accordance with still another embodiment;

FIGS. 7, 8A, and 8B illustrate diagrams showing a semiconductor device in accordance with still another embodiment;

FIGS. 9, 10A, and 10B illustrate diagrams showing a semiconductor device in accordance with still another embodiment;

FIGS. 11, 12A, and 12B illustrate diagrams showing a semiconductor device in accordance with still another embodiment;

FIGS. 13A and 13B, and FIGS. 14A and 14B illustrate diagrams showing a semiconductor device in accordance with still another embodiment;

FIGS. 15A and 15B, and FIGS. 16A and 16B illustrate diagrams showing a semiconductor device in accordance with still another embodiment;

FIGS. 17, 18A, and 18B illustrate diagrams showing a semiconductor device in accordance with still another embodiment;

FIGS. 19, 20A, and 20B illustrate diagrams showing a semiconductor device in accordance with still another embodiment;

FIGS. 21, 22A, and 22B illustrate diagrams showing a semiconductor device in accordance with still another embodiment;

FIGS. 23, 24A, and 2413 illustrate diagrams showing a semiconductor device in accordance with still another embodiment;

FIGS. 25A and 25B, and FIGS. 26A and 26B illustrate diagrams showing a semiconductor device in accordance with still another embodiment;

FIGS. 27A and 27B, and FIGS. 28A and 28B illustrate diagrams showing a semiconductor device in accordance with still another embodiment;

FIGS. 29A and 29B illustrate diagrams showing a semiconductor device in accordance with still another embodiment;

FIGS. 30A and 30B illustrate diagrams showing a semiconductor device in accordance with still another embodiment;

FIGS. 31A and 31B illustrate diagrams showing a semiconductor device in accordance with still another embodiment;

FIGS. 32A and 32B illustrate diagrams showing a semiconductor device in accordance with still another embodiment;

FIGS. 33A and 33B illustrate diagrams showing a semiconductor device in accordance with still another embodiment;

FIGS. 34A and 34B illustrate diagrams showing a semiconductor device in accordance with still another embodiment;

FIGS. 35A and 35B illustrate diagrams showing a semiconductor device in accordance with still another embodiment;

FIGS. 36A and 36B illustrate diagrams showing a semiconductor device in accordance with still another embodiment;

FIGS. 37, 38A, and 38B illustrate diagrams showing a semiconductor device in accordance with still another embodiment;

FIGS. 39, 40A, and 40B illustrate diagrams showing a semiconductor device in accordance with still another embodiment;

FIGS. 41, 42A, and 42B illustrate diagrams showing a semiconductor device in accordance with still another embodiment;

FIGS. 43, 44A, and 44B illustrate diagrams showing a semiconductor device in accordance with still another embodiment;

FIGS. 45, 46A, and 46B illustrate diagrams showing a semiconductor device in accordance with still another embodiment;

FIGS. 47, 48A, and 48B illustrate diagrams showing a semiconductor device in accordance with still another embodiment;

FIGS. 49, 50A, and 50B illustrate diagrams showing a semiconductor device in accordance with still another embodiment;

FIGS. 51, 52A, and 52B illustrate diagrams showing a semiconductor device in accordance with still another embodiment;

FIG. 53 illustrates a diagram schematically showing a memory card including a semiconductor device in accordance with an embodiment;

FIG. 54 illustrates a block diagram showing an electronic apparatus including a semiconductor device in accordance with an embodiment;

FIG. 55 illustrates a block diagram showing a data storage apparatus including a semiconductor device in accordance with an embodiment;

FIG. 56 illustrates a diagram showing an electronic apparatus including a semiconductor device in accordance with an embodiment;

FIG. 57 illustrates a block diagram schematically showing an electronic system including a semiconductor device in accordance with an embodiment; and

FIG. 58 illustrates a diagram schematically showing an electronic product including a semiconductor device in accordance with an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Embodiments are described herein with reference to cross-sectional views, plan views, and block diagrams that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

Spatially relative terms, such as “beneath,” “below,” “lower,” “above,” “upper,” and the like may be used herein to describe the relationship of one element or feature to another, as illustrated in the drawings. It will be understood that such descriptions are intended to encompass different orientations in use or operation in addition to orientations depicted in the drawings. For example, if a device is turned over, elements described as “below” or “beneath” other elements or features would then be oriented “above” the other elements or features. Thus, the term “below” is intended to mean both above and below, depending upon overall device orientation. Also, the device may be reoriented in other ways (rotated 90 degrees or at other orientations) and the descriptors used herein should be interpreted accordingly.

It will be understood that, although the terms first, second, A, B, etc. may be used herein in reference to elements, such elements should not be construed as limited by these terms. For example, a first element could be termed a second element, and a second element could be termed a first element, without departing from the scope of the present application. Herein, the term “and/or” includes any and all combinations of one or more referents.

The terminology used herein to describe embodiments is not intended to limit the scope of the application. The articles “a,” “an,” and “the” are singular in that they have a single referent; however the use of the singular form in the present document should not preclude the presence of more than one referent. In other words, elements referred to in the singular may number one or more, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein are to be interpreted as is customary in the art to which this application belongs. It will be further understood that terms in common usage should also be interpreted as is customary in the relevant art and not in an idealized or overly formal sense unless expressly so defined herein.

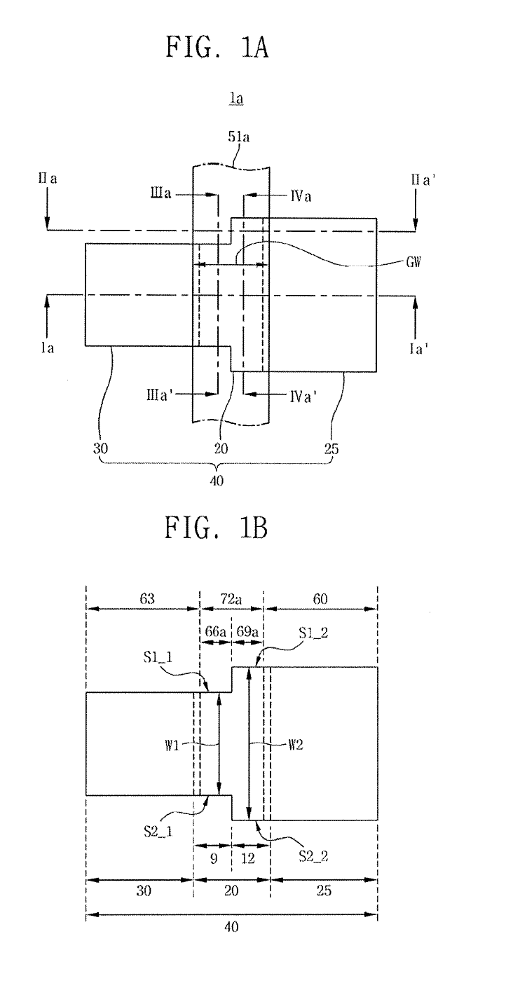

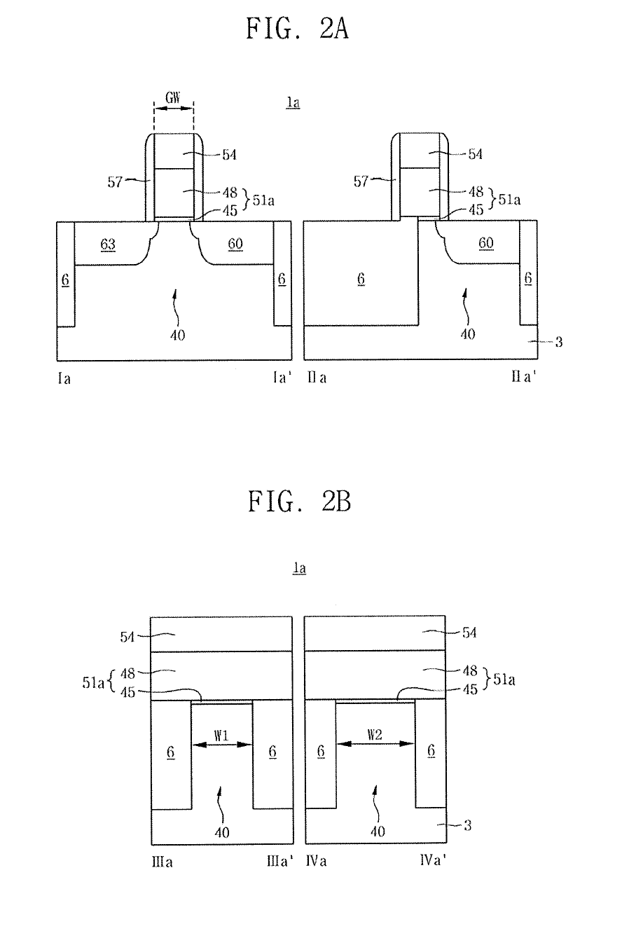

FIG. 1A illustrates a plan view showing a semiconductor device in accordance with an embodiment. FIG. 1B illustrates a plan view for describing some elements of a semiconductor device in accordance with an embodiment. FIGS. 2A and 2B illustrate cross-sectional views showing a semiconductor device in accordance with an embodiment. In FIGS. 2A and 2B, FIG. 2A illustrates a cross-sectional view showing an area taken along line Ia-Ia′ of FIG. 1A and an area taken along line IIa-IIa′ of FIG. 1A, and FIG. 2B illustrates a cross-sectional view showing an area taken along line IIIa-IIIa′ of FIG. 1A and line IVa-IVa′ of FIG. 1A.

Referring to FIGS. 1A and 1B, and FIGS. 2A and 2B, a semiconductor device 1a in accordance with an embodiment may include an active region 40 on a semiconductor substrate 3, a gate structure 51a on the active region 40, and a drain region 60 and a source region 63 in the active region 40 at sides, e.g., opposite sides, of the gate structure 51a. The semiconductor substrate 3 may be a semiconductor substrate formed of a silicon material. In an implementation, the semiconductor substrate 3 may be a compound semiconductor substrate including at least two elements of Group III, Group IV, and Group V elements of the periodic table.

The active region 40 may be defined by an isolation region 6 formed in the semiconductor substrate 3. The isolation region 6 may be a shallow trench isolation layer.

The gate structure 51a may include a gate electrode 48 (on the active region 40) and a gate dielectric 45 (between the gate electrode 48 and the active region 40). The gate electrode 48 may cross the active region 40. The gate dielectric 45 may include silicon oxide. The gate dielectric 45 may include at least one of silicon oxide or a high-k dielectric. The gate electrode 48 may be formed of a conductive material. For example, the gate electrode 48 may include at least one of polysilicon, a metal, or a metal silicide.

A gate capping pattern 54 may be on the gate electrode 48. The gate capping pattern 54 may be formed of an insulating material, e.g., silicon oxide or silicon nitride. A gate spacer 57 may be on side surfaces of the gate structure 51a and the gate capping pattern 54. The gate spacer 57 may be formed of an insulating material, e.g., silicon nitride or a high-k dielectric material.

The active region 40 may include a first side surface and a second side surface, the first side surface and the second side surface facing each other. The first and second side surfaces of the active region 40 may intersect and may be overlapped by the gate structure 51a. For example, the gate structure 51a may overlie the first and second side surfaces of the active region 40. The first side surface of the active region 40 may include a first part S1_{—}1 and a second part S1_{—}2, and the second side surface of the active region 40 may include a first part S2_{—}1 and a second pan S2_{—}2. In the active region 40, the first part S1_{—}1 of the first side surface may face the first part S2_{—}1 of the second side surface, and the second part S1_{—}2 of the first side surface may face the second part S2_{—}2 of the second side surface. In the active region 40, the first part S1_{—}1 of the first side surface may be parallel to the first part S2_{—}1 of the second side surface, and the second part S1_{—}2 of the first side surface may be parallel to the second part S2_{—}2 of the second side surface.

In an implementation, a “width of an active region” may be understood as a distance between the first side surface and the second side surface of the active region 40.

The active region 40 may include a first part 20 (overlapped by the gate structure 51a), and a second part 25 and a third part 30 (facing each other with the first part 20 interposed therebetween). The first part 20 of the active region 40 may be overlapped by the gate electrode 48 of the gate structure 51a, e.g., the gate electrode 48 of the gate structure 51a may overlie the first part 20 of the active region 40. The gate electrode 48 at a portion overlapping the active region 40 may have a uniform width GW, and the first part 20 of the active region 40 overlapped by the gate electrode 48 may have non-uniform widths W1 and W2. The direction of the width GW of the gate electrode 48 and the direction of the widths W1 and W2 of the first part 20 of the active region 40 may be perpendicular to each other.

The first part 20 of the active region 40 may have a smaller width at a portion spaced apart from the second part 25 than at a portion in contact with or adjacent to the second part 25. For example, the first part 20 of the active region 40 may have a stepped structure or shape including at least one discontinuous change in width therein. For example, the first part 20 of the active region 40 may include a first portion 9 and a second portion 12. The width W2 of the second portion 12 of the active region 40 may be greater than the width W1 of the first portion 9 of the active region 40.

The second portion 12 of the active region 40 may be closer to the second part 25 of the active region 40 than to the third part 30 of the active region 40.

The second portion 12 of the active region 40 may be continuously connected to the second part 25 of the active region 40. The first portion 9 of the active region 40 may be continuously connected to the third part 30 of the active region 40. The second portion 12 of the active region 40 and the first portion 9 of the active region 40 may be continuously connected.

In the active region 40, the second portion 12 may be interposed between the first portion 9 and the second part 25, and the first portion 9 may be interposed between the second portion 12 and the third part 30. In the active region 40, the second part 25 may have the same width W2 as the second portion 12, and the third part 30 may have the same width W1 as the first portion 9.

The source region 63 and the drain region 60 may be disposed in the active region 40 adjacent to sides of the gate structure 51a. The drain region 60 may be formed in the second part 25 of the active region 40. The source region 63 may be formed in the third part 30 of the active region 40.

The active region 40 may be of a first conductivity type, and the drain region 60 and the source region 63 may be of a second conductivity type different from the first conductivity type. For example, when the first conductivity type is P-type, the second conductivity type may be N-type. In an implementation, when the first conductivity type is N-type, the second conductivity type may be P-type.

In an implementation, each of the drain region 60 and the source region 63 may have a lightly doped drain (LDD) structure.

In the active region 40, a channel region 72a may be defined in the active region 40 between the drain region 60 and the source region 63. The channel region 72a may be in the first part 20 of the active region 40. The channel region 72a may have a different conductivity type from the drain region 60 and the source region 63.

The channel region 72a may have a relatively greater channel width at a portion in contact with or adjacent to the drain region 60 than at a portion spaced apart from the drain region 60.

In the channel region 72a, a channel region in the first portion 9 of the active region 40 may be defined as a first channel region 66a, and a channel region in the second portion 12 of the active region 40 may be defined as a second channel region 69a. The first channel region 66a may have a first channel width W1, and the second channel region 69a may have a second channel width W2 (greater than the first channel width W1). The first channel region 66a may be in contact with the source region 63 to form a PN junction, and the second channel region 69a may be in contact with the drain region 60 to form a PN junction.

The source region 63, the drain region 60, the channel region 72a, and the gate structure 51a may configure or form a transistor.

The second channel region 69a in contact with the drain region 60 may have a greater width than the first channel region 66a spaced apart from the drain region 60, and a corner effect of the transistor may be improved. For example, a hump effect of the transistor may be improved. By improving the corner effect of the transistor, reliability of a semiconductor device may increase.

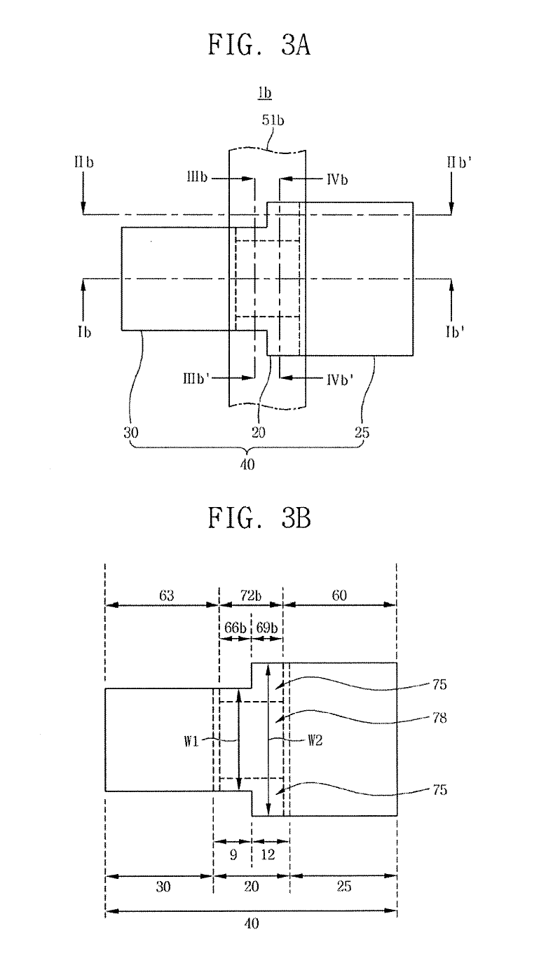

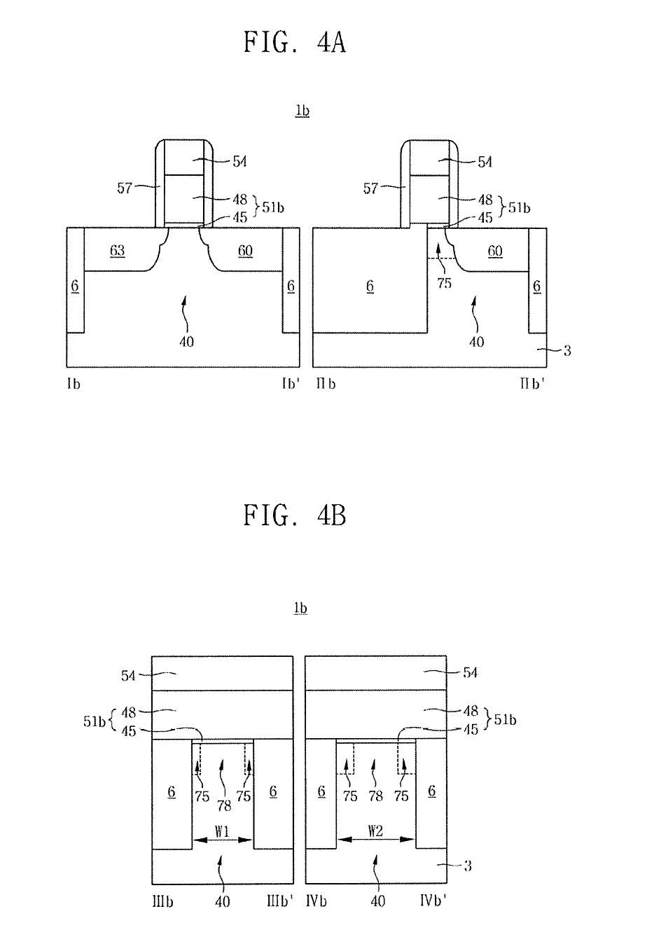

FIG. 3A illustrates a plan view showing a semiconductor device in accordance with another embodiment. FIG. 3B illustrates a plan view showing some elements of a semiconductor device in accordance with another embodiment. FIGS. 4A and 4B illustrate cross-sectional views showing a semiconductor device in accordance with another embodiment. In FIGS. 4A and 4B, FIG. 4A illustrates a cross-sectional view showing an area taken along line Ib-Ib′ of FIG. 3A and an area taken along line IIb-IIb′ of FIG. 3A, and FIG. 4B illustrates a cross-sectional view showing an area taken along line IIIb-IIIb′ of FIG. 3A and an area taken along line IVa-IVa′ of FIG. 3A.

Referring to FIGS. 3A and 3B and FIGS. 4A and 4B, a semiconductor device 1b in accordance with another embodiment may include the active region 40 on the semiconductor substrate 3, a gate structure 51b on the active region 40, and the source region 63 and drain region 60 in the active region 40 at sides of the gate structure 51b.

The gate structure 51b, as described in FIGS. 2A and 2B, may include the gate electrode 48 on the active region 40, and the gate dielectric 45 between the gate electrode 48 and the active region 40.

The active region 40, as described in FIGS. 1A and 1B and FIGS. 2A and 2B, may include a first part 20 overlapped by the gate structure 51b, and a second part 25 and a third part 30 facing each other with the first part 20 interposed therebetween.

The first part 20 of the active region 40 may have a smaller width at a portion that is spaced apart from the second part 25 than at a portion that is in contact with or connected to the second part 25. In the active region 40, the first part 20 may include the first portion 9 connected to the third part 30, and the second portion 12 having a greater width than the first portion 9 and connected to the second part 25.

In addition, as described in FIGS. 1A and 1B and FIGS. 2A and 2B, the drain region 60 may be in the second part 25 of the active region 40, and the source region 63 may be in the third part 30 of the active region 40. A channel region 72b may be between the source region 63 and the drain region 60. The channel region 72b may be in the first part 20 of the active region 40.

In the channel region 72b, a channel region in the first portion 9 of the active region 40 may be defined as a first channel region 66b, and a channel region in the second portion 12 of the active region 40 may be defined as a second channel region 69b.

In addition, the channel region 72b may include a first channel concentration area 78 and second channel concentration areas 75. The first channel concentration area 78 may be located at a center of the channel region 72b and may be between the second channel concentration areas 75. The second channel concentration areas 75 may be between the isolation region 6 and the first channel concentration area 78. The second channel concentration areas 75 may have a higher channel concentration than the first channel concentration area 78.

The source region 63, the drain region 60, the channel region 72b, and the gate structure 51b may configure a transistor.

The second channel region 69b (that is continuously connected to the drain region 60) may have a greater width than the first channel region 66b (that is spaced apart from the drain region 60). Thus, the second channel region 69b may help improve a corner effect, such as a hump effect, of the transistor.

In addition, the second channel concentration areas 75 (having a relatively higher channel concentration than the first channel concentration area 78) may be at ends of the channel region 72b that are adjacent to the isolation region 6, and a hump effect of the transistor may be improved.

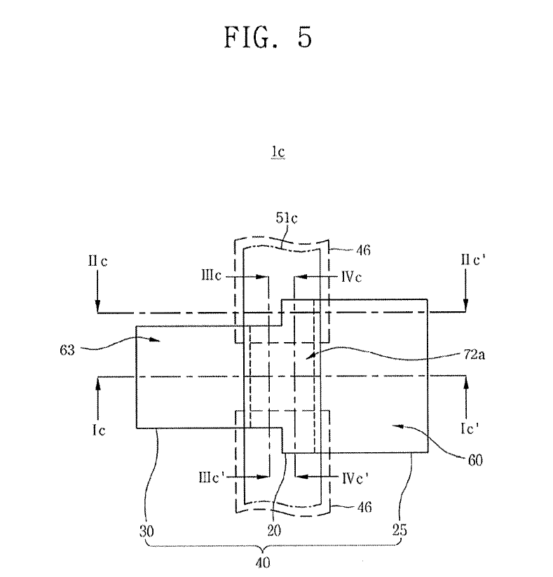

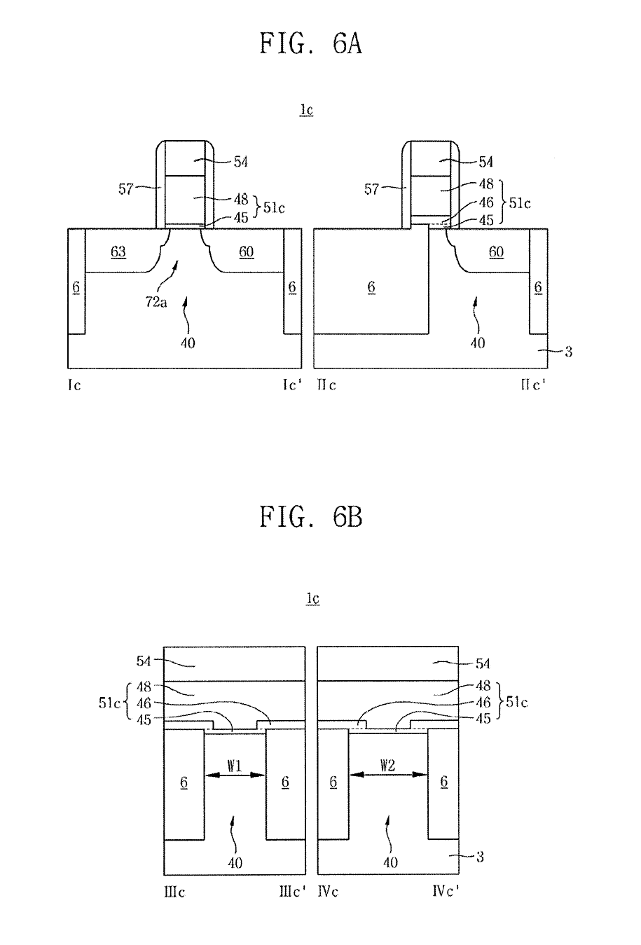

FIG. 5 illustrates a plan view showing a semiconductor device in accordance with still another embodiment. FIGS. 6A and 6B illustrate cross-sectional views showing a semiconductor device in accordance with still another embodiment. In FIGS. 6A and 6B, FIG. 6A illustrates a cross-sectional view showing an area taken along line Ic-Ic′ of FIG. 5 and an area taken along line IIc-IIc′ of FIG. 5, and FIG. 6B illustrates a cross-sectional view showing an area taken along line IIIc-IIIc′ of FIG. 5 and an area taken along line IVc-IVc′ of FIG. 5.

Referring to FIGS. 5, 6A, and 613, a semiconductor device Ic in accordance with still another embodiment may include an active region 40 on a semiconductor substrate 3, a gate structure 51c crossing the active region 40, and the source region 63 and the drain region 60 in the active region 40 at sides of the gate structure 51c.

As described with respect to FIGS. 1A and 1B and FIGS. 2A and 2B, the active region 40 may include a first part 20 overlapped by the gate structure S c, and a second part 25 and a third part 30 facing each other with the first part 20 interposed therebetween. The first part 20, as described with respect to FIG. 1B, may include the first portion 9 and the second portion 12 (having a width greater than the first portion 9 and in contact with the second part 25). In addition, as described with respect to FIGS. 1A and 1B and FIGS. 2A and 2B, the drain region 60 may be in the second part 25 of the active region 40, and the source region 63 may be in the third part 30 of the active region 40. The channel region 72a may be defined in the first part 20 of the active region 40 between the source region 63 and the drain region 60, as shown in FIGS. 1A and 1B and FIGS. 2A and 2B.

The gate structure 51i may include a gate dielectric 45 and a gate electrode 48 sequentially stacked on the active region 40. The gate electrode 48 may cross the active region 40.

Buffer dielectric patterns 46 may be disposed under the gate electrode 48 in order to help improve a corner effect of the transistor. The buffer dielectric patterns 46 may overlap ends of the first part 20 of the active region 40 that are adjacent to the isolation region 6. In the ends of the first part 20 of the active region 40 that are adjacent to the isolation region 6, the buffer dielectric patterns 46 may be interposed between the gate dielectric 45 and the gate electrode 48. In an implementation, the buffer dielectric patterns 46 may extend between the gate electrode 48 and the isolation region 6. The buffer dielectric patterns 46 may include at least one of silicon oxide or a high-k dielectric.

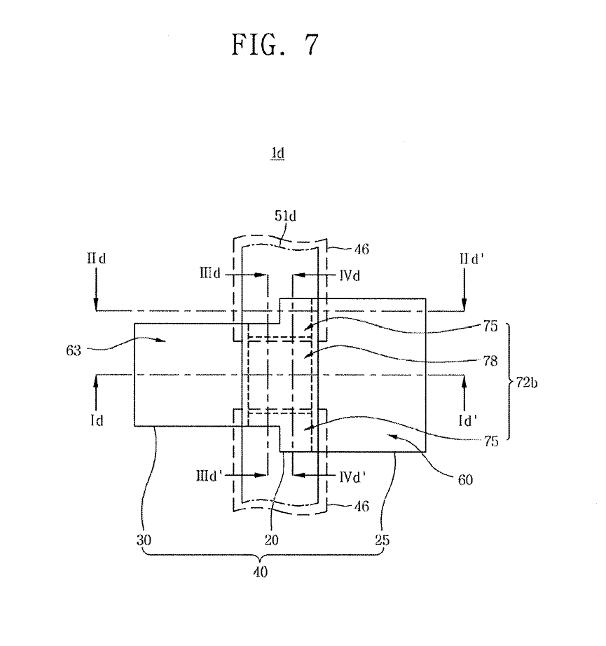

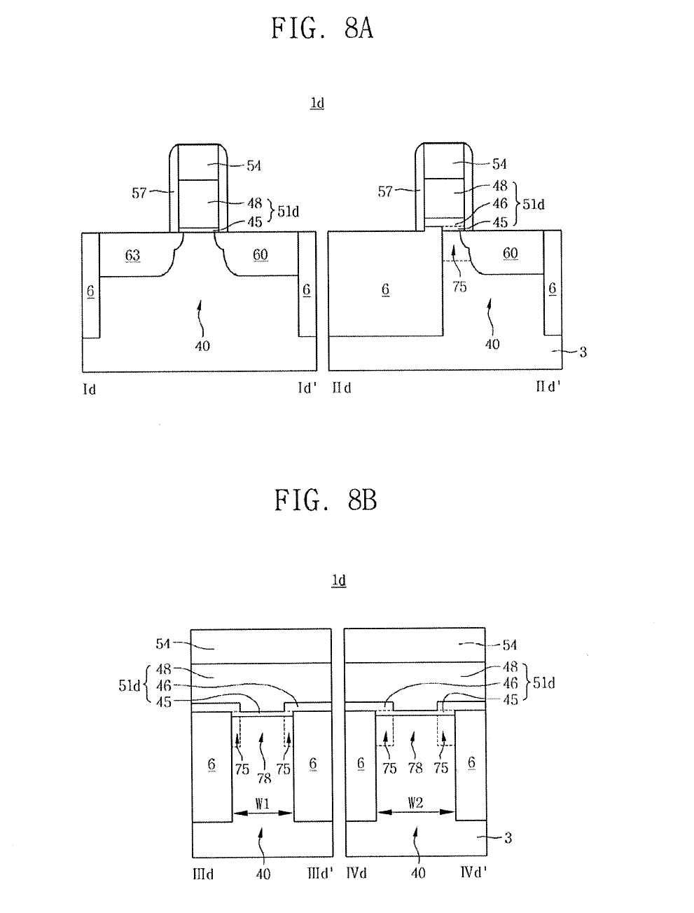

FIG. 7 illustrates a plan view showing a semiconductor device in accordance with still another embodiment. FIGS. 8A and 8B illustrate cross-sectional views showing a semiconductor device in accordance with still another embodiment. In FIGS. 8A and 8B, FIG. 8A illustrates a cross-sectional view showing an area taken along line Id-Id′ of FIG. 7 and an area taken along line IId-IId′ of FIG. 7, and FIG. 8B illustrates a cross-sectional view showing an area taken along line IIId-IIId′ of FIG. 7 and an area taken along line IVd-IVd′ of FIG. 7.

Referring to FIGS. 7, 8A, and 8B, a semiconductor device 1d in accordance with still another embodiment may include an active region 40 on a semiconductor substrate 3, a gate structure 51d crossing the active region 40, and the source region 63 and the drain region 60 in the active region 40 at sides of the gate structure 51d.

As described in FIGS. 1A and 11B and FIGS. 2A and 2B, the active region 40 may include a first part 20 overlapped by the gate structure 51d, and a second part 25 and a third part 30 facing each other with the first part 20 therebetween. The first part 20, as described in FIG. 1B, may include the first portion 9, and the second portion 12 (having a greater width than the first portion 9 and in contact with the second part 25). In addition, as described in FIGS. 1A and 1B and FIGS. 2A and 2B, the drain region 60 may be in the second part 25 of the active region 40, and the source region 63 may be in the third part 30 of the active region 40.

The channel region 72b as described in FIGS. 3A and 3B and FIGS. 4A and 4B, may be defined between the source region 63 and the drain region 60. Accordingly, the channel region 72b, as described in FIGS. 3A and 3B and FIGS. 4A and 4B, may include the first channel concentration area 78 at the center of the first part 20 of the active region 40, and the second channel concentration areas 75 at the ends of the first part 20 of the active region 40. In addition, the channel region 72b may have a greater width at a portion in contact with the drain region 60 than at a portion spaced apart from the drain region 60.

The buffer dielectric patterns 46 as shown in FIGS. 5, 6A, and 6B may be disposed under the gate electrode 48. The buffer dielectric patterns 46 may overlap the ends of the first part 20 of the active region 40 that are adjacent to the isolation region 6, and may be between the gate dielectric 45 and the gate electrode 48. Further, the buffer dielectric patterns 46 may extend between the gate electrode 48 and the isolation region 6.

The buffer dielectric patterns 46, the second channel concentration areas 75, and the first part 20 of the active region 40 may help improve hump characteristics of the transistor.

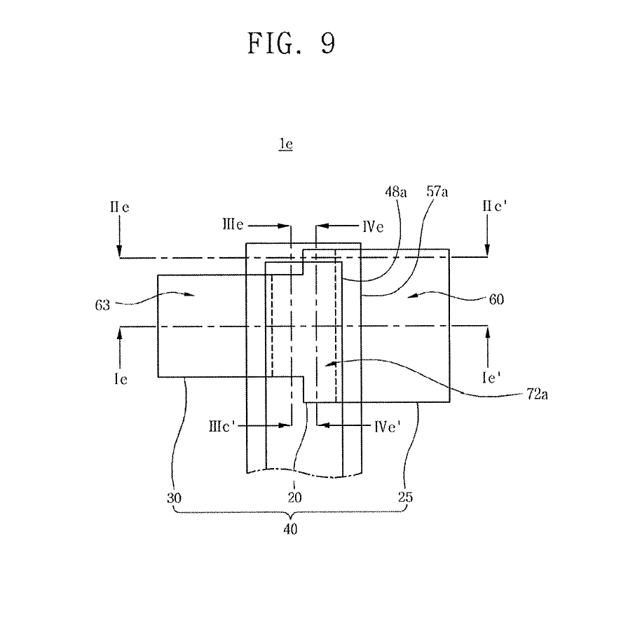

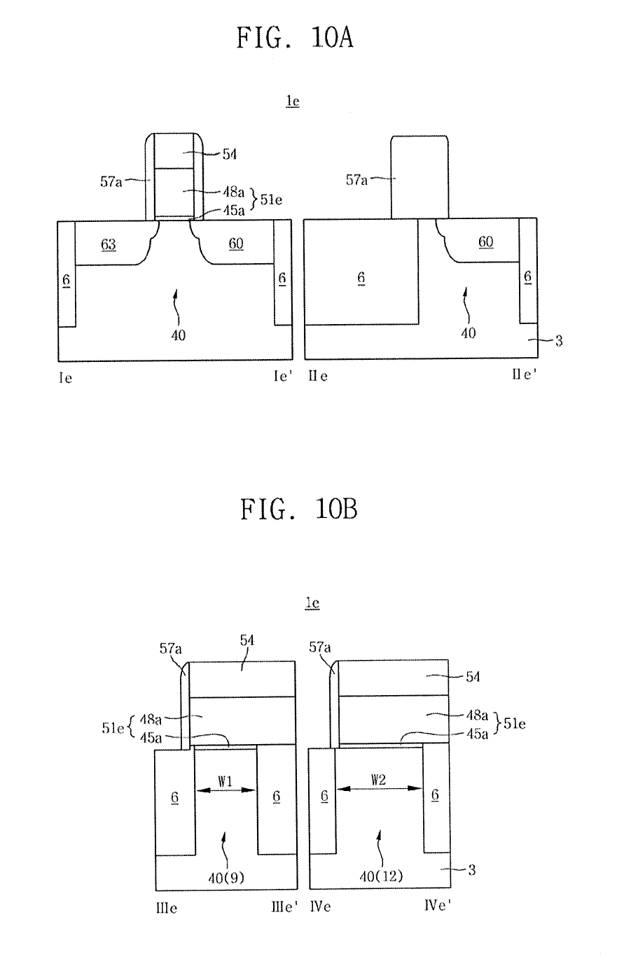

FIG. 9 illustrates a plan view showing a semiconductor device in accordance with still another embodiment. FIGS. 10A and 10B illustrate cross-sectional views showing a semiconductor device in accordance with still another embodiment. In FIGS. 10A and 10B, FIG. 10A illustrates a cross-sectional view showing an area taken along line Ie-Ie′ of FIG. 9 and an area taken along line IIe-IIe′ of FIG. 9, and FIG. 101 illustrates a cross-sectional view showing an area taken along line IIIe-Ille′ of FIG. 9 and an area taken along line IVe-IVe′ of FIG. 9.

Referring to FIGS. 9, 10A, and 10B, a semiconductor device 1e in accordance with still another embodiment may include an active region 40 disposed on a semiconductor substrate 3, a gate structure 51e disposed on the active region 40, and the source region 63 and the drain region 60 formed in the active region 40 disposed at both sides of the gate structure 51e.

The active region 40 may include a first part 20, and a second part 25 and a third part 30 facing each other with the first part 20 therebetween. The first part 20 of the active region 40, as described in FIGS. 1A and 1B and FIGS. 2A and 2B, may include the first portion 9, and the second portion 12 having a greater width than the first portion 9 and in contact with the second part 25. In addition, as described in FIGS. 1A and 1B and FIGS. 2A and 2B, the drain region 60 may be in the second part 25 of the active region 40, and the source region 63 may be in the third part 30 of the active region 40. The channel region 72a as described in FIGS. 1A and 1B and FIGS. 2A and 2B may be in the first part 20 of the active region 40 between the source region 63 and the drain region 60. The channel region 72a, as described in FIGS. 1A and 1B and FIGS. 2A and 2B, may include a first channel region 66a in the first portion 9, and a second channel region 69a in the second portion 12. The second channel region 69a may be in contact with the drain region 60, and may have a greater width than the first channel region 66a.

The gate structure 51e may include a gate dielectric 45a and a gate electrode 48a. The gate dielectric 45a may be between the gate electrode 48a and the active region 40.

A gate capping pattern 54 self-aligned with the gate electrode 48a may be on the gate electrode 48a. A gate spacer 57a may be on side surfaces of the gate structure 51e and the gate capping pattern 54.

The gate electrode 48a may have a portion overlapping the active region 40 and extending onto the isolation region 6. The gate electrode 48a may cover the first portion 9 of the active region 40, and may partially cover the second portion 12 of the active region 40. For example, one end of the second portion 12 of the active region 40 may not be overlapped by the gate electrode 48a. In an implementation, both ends of the second portion 12 of the active region 40 may be ends that are adjacent to the isolation region 6. In addition, the end that is not overlapped by the gate electrode 48a among the ends of the second portion 12 of the active region 40 may be overlapped by the gate spacer 57a.

The channel region 72a may have a greater width at a portion thereof in contact with the drain region 60 than at a portion thereof that is spaced apart from the drain region 60, and hump characteristics of the transistor may be improved. In addition, a portion of an end of the first part 20 in which the channel region 72a is formed may not be overlapped by the gate electrode 48a, and the corner effect of the transistor may be improved.

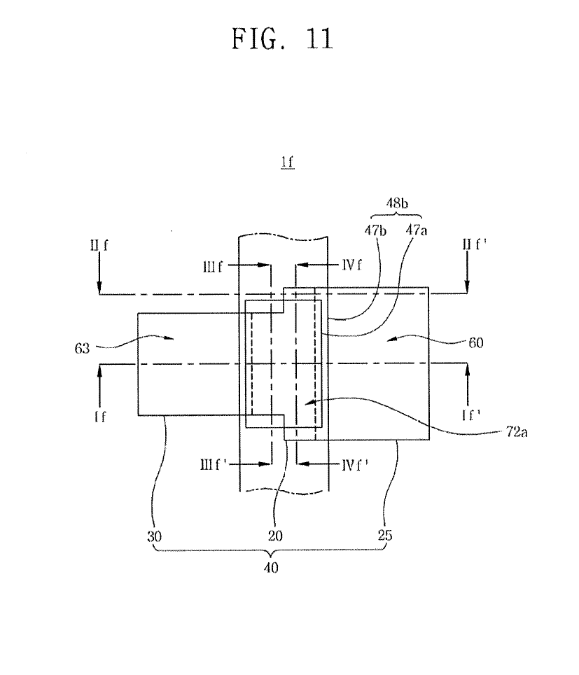

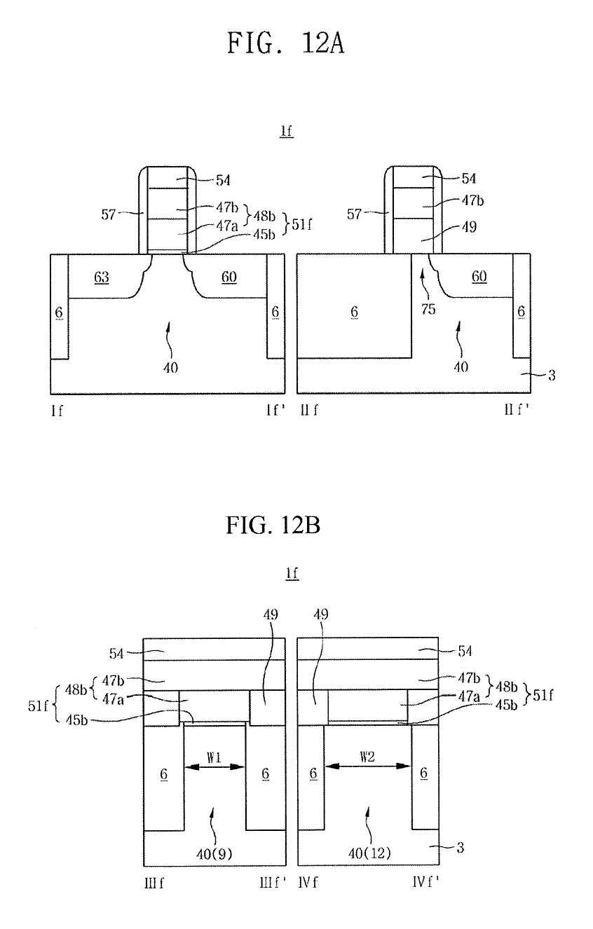

FIG. 11 illustrates a plan view showing a semiconductor device in accordance with still another embodiment. FIGS. 12A and 12B illustrate cross-sectional views showing a semiconductor device in accordance with still another embodiment. In FIGS. 12A and 12B. FIG. 12A illustrates a cross-sectional view showing an area taken along line If-If of FIG. 11 and an area taken along line IIf-IIf of FIG. 11, and FIG. 12B illustrates a cross-sectional view showing an area taken along line IIIf-IIIf of FIG. 11 and an area taken along line IVf-IVf of FIG. 11.

Referring to FIGS. 11, 12A, and 12B, a semiconductor device 1f in accordance with still another embodiment may include an active region 40 on a semiconductor substrate 3, a gate structure 51f on the active region 40, and the source region 63 and the drain region 60 in the active region 40 at sides of the gate structure 51f.

The active region 40 may include a first part 20, and a second part 25 and a third part 30 facing each other with the first part 20 therebetween. The first part 20 of the active region 40, as described in FIGS. 1A and 1B and FIGS. 2A and 2B, may include the first portion 9, and the second portion 12 (having a width W2 greater than a width W1 of the first portion 9 and in contact with the second part 25). In addition, as described in FIGS. 1A and 1B and FIGS. 2A and 2B, the drain region 60 may be in the second part 25 of the active region 40, and the source region 63 may be in the third part 30 of the active region 40. The channel region 72a, as described in FIGS. 1A and 1B and FIGS. 2A and 2B, may be between the source region 63 and the drain region 60. The channel region 72a, as described in FIGS. 1A and 1B and FIGS. 2A and 2B, may include a first channel region 66a in the first portion 9, and a second channel region 69a in the second portion 12.

The gate structure 51f may include a gate dielectric 45b and a gate electrode 48b. The gate electrode 48b may have a portion overlapping the active region 40, and extending onto the isolation region 6. The gate electrode 48b may include a lower gate electrode 47a, and an upper gate electrode 47b on the lower gate electrode 47a. The gate dielectric 45b may be interposed between the lower gate electrode 47a and the active region 40.

The lower gate electrode 47a may cover the first portion 9, and may partially cover the second portion 12. Accordingly, the lower gate electrode 47a may not overlap both ends of the second portion 12. Here, both ends of the second portion 12 may be ends that are adjacent to the isolation region 6. The upper gate electrode 47b may overlap the lower gate electrode 47a, may cross over the active region 40, and may extend onto the isolation region 6.

A gate capping pattern 54 may be on the upper gate electrode 47b. An insulating pattern 49 may be under the upper gate electrode 47b. The insulating pattern 49 may be between the upper gate electrode 47b and the isolation region 6, and between the ends of the second portion 12 that are not overlapped by the lower gate electrode 47a, and the upper gate electrode 47b. The insulating pattern 49 may be formed of an insulating material such as silicon oxide or silicon nitride.

The channel region 72a may have a greater width at a portion in contact with the drain region 60 than at a portion spaced apart from the drain region 60, and hump characteristics of the transistor may be improved. In addition, both ends of the second portion 12 of the first part 20 (in which the channel region 72a is formed) may not be overlapped by the lower gate electrode 47a, and hump characteristics of the transistor may be improved.

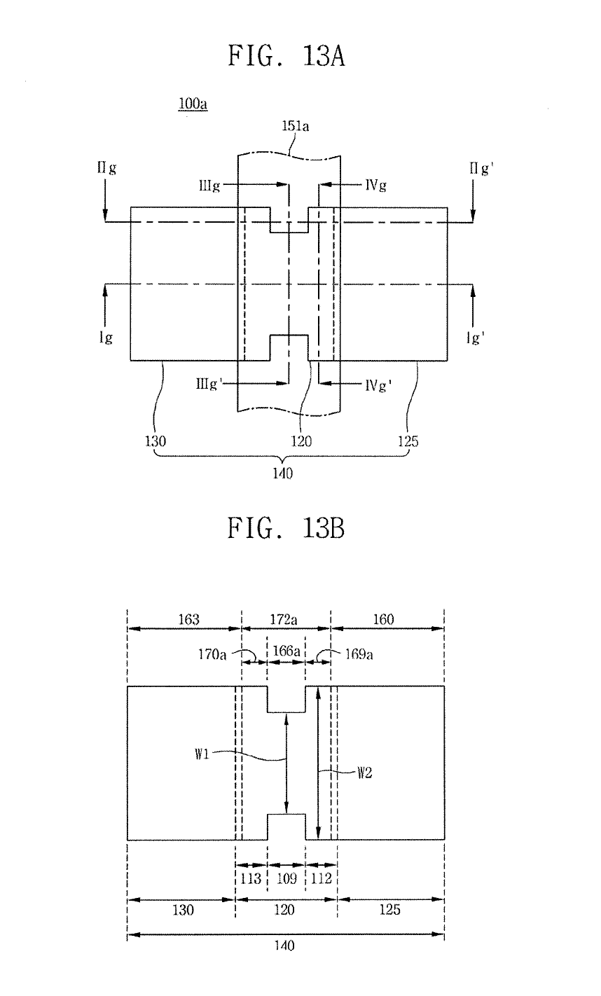

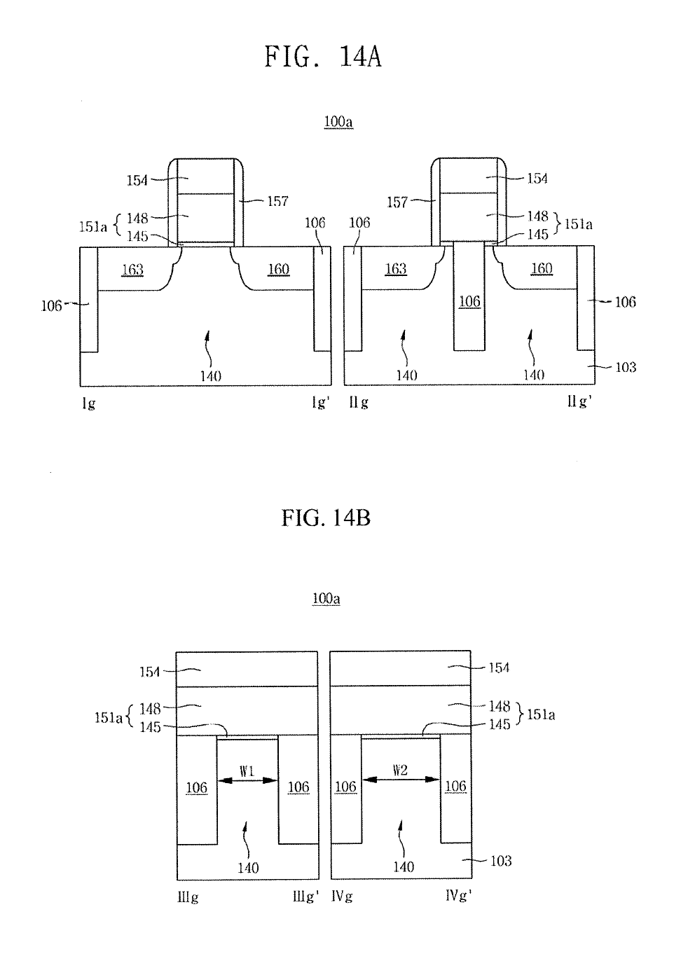

FIG. 13A illustrates a plan view showing a semiconductor device in accordance with still another embodiment. FIG. 13B illustrates a plan view for describing some elements of a semiconductor device in accordance with still another embodiment. FIGS. 14A and 14B illustrate cross-sectional views showing a semiconductor device in accordance with still another embodiment. In FIGS. 14A and 14B, FIG. 14A illustrates a cross-sectional view showing an area taken along line Ig-Ig′ of FIG. 13A and an area taken along line IIg-IIg′ of FIG. 13A, and FIG. 14B illustrates a cross-sectional view showing an area taken along line IIIg-IIIg′ of FIG. 13A and an area taken along line IVg-IVg′ of FIG. 13A.

Referring to FIGS. 13A and 13B and FIGS. 14A and 1411, a semiconductor device 100a in accordance with still another embodiment may include an active region 140 on a semiconductor substrate 103, a gate structure 151a on the active region 140, and a first source/drain region 160 and a second source/drain region 163 in the active region 140 at sides of the gate structure 151a.

The active region 140 may be defined by an isolation region 106 in the semiconductor substrate 103. The isolation region 106 may be a shallow trench isolation layer.

The gate structure 151a may include a gate electrode 148 on the active region 140, and a gate dielectric 145 between the active region 140 and the gate electrode 148. The gate electrode 148 may cross the active region 140 and may extend onto the isolation region 106.

A gate capping pattern 154 may be on the gate electrode 148. The gate capping pattern 154 may be formed of an insulating material, such as silicon oxide or silicon nitride.

A gate spacer 157 may be on side surfaces of the gate structure 151a and the gate capping pattern 154. The gate spacer 157 may be formed of an insulating material, such as silicon nitride or a high-k dielectric material.

The active region 140 may include a first part 120 overlapped by the gate structure 151a, and a second part 125 and a third part 130 facing each other with the first part 120 interposed therebetween. In the active region 140, the first part 120 may be a portion overlapped by the gate electrode 148 of the gate structure 151a.

The active region 140 may include a concave portion, e.g., a reduced width portion, at the first part 120 overlapped by the gate structure 151a. In the active region 140, the first part 120 may have a smaller width at a portion spaced apart from the second and third parts 125 and 130 than at a part adjacent to or in contact with the second and third parts 125 and 130.

In the active region 140, the first part 120 may include a first portion 109, and second and third portions 112 and 113 facing each other with the first portion 109 therebetween. The first portion 109 may have a first width W1, and the second and the third portions 112 and 113 may each have a second width W2 greater than the first width W1.

In the active region 140, the first portion 109 may be between the second and third portions 112 and 113, and may be continuously connected to the second and third portions 112 and 113. In the active region 140, the second portion 112 may be between the first portion 109 and the second part 125, and the third portion 113 may be between the first portion 109 and the third part 130. The second portion 112 of the active region 140 may be continuously connected to the first portion 109 of the active region 140 and the second part 125 of the active region 140. The third portion 113 of the active region 140 may be continuously connected to the first portion 109 of the active region 140 and the third part 130 of the active region 140. In the active region 140, the second and third parts 125 and 130 may have the same width W2 as the second and third portions 112 and 113.

The first source/drain region 160 and the second source/drain region 163 may be in the active region 140 adjacent to sides of the gate structure 151a. One of the first source/drain region 160 and the second source/drain region 163 may be a source region of a transistor, and the other may be a drain region of the transistor. The active region between the first source/drain region 160 and the second source/drain region 163 may be defined as a channel region 172a.

The active region 140 may be a first conductivity type, and the first source/drain region 160 and the second source/drain region 163 may be a second conductivity type that is different from the first conductivity type. For example, when the first conductivity type is P-type, the second conductivity type may be N-type. Otherwise, when the first conductivity type is N-type, the second conductivity type may be P-type. The first source/drain region 160 may be in the second part 125 of the active region 140. The second source/drain region 163 may be in the third part 130 of the active region 140. The channel region 172a may be in the first part 120 of the active region 140.

The channel region 172a may have a greater width at a portion in contact with or adjacent to the first and second source/drain regions 160 and 163 than at a portion spaced apart from the first and second source/drain regions 160 and 163. In the channel region 172a, a channel region in the first portion 109 of the active region 140 may be defined as a first channel region 166a, a channel region in the second portion 112 of the active region 140 may be defined as a second channel region 169a, and a channel region in the third portion 113 of the active region 140 may be defined as a third channel region 170a. The first channel region 166a may have a first channel width W1, and the second and third channel regions 169a and 170a may have a second channel width W2 greater than the first channel width W1. Here, widths of the first to third channel regions 166a, 169a, and 170a may be distances between a first side surface and a second side surface facing each other in the first part 120 of the active region 140. Here, the two opposite first and second side surfaces of the first part 120 of the active region 140 may be side surfaces overlapped by the gate structure 151a and adjacent to the isolation region 6.

The channel region 172a may have a greater width at a portion in contact with or adjacent to the first and second source/drain regions 160 and 163 than at a portion spaced apart from the first and second source/drain regions 160 and 163, and hump characteristics of the transistor may be improved.

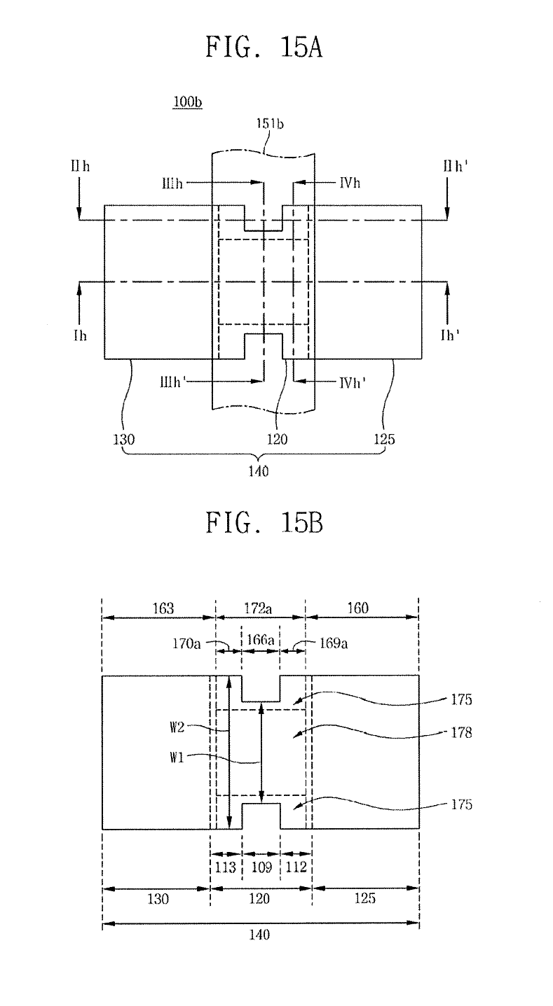

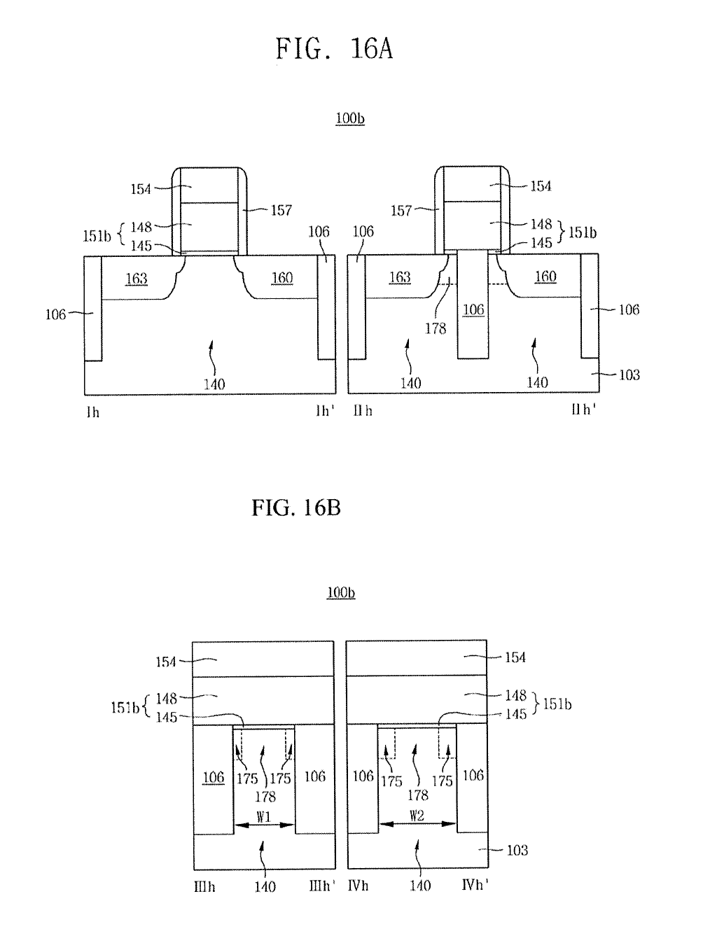

FIG. 15A illustrates a plan view showing a semiconductor device in accordance with still another embodiment. FIG. 15B illustrates a plan view showing some elements of the semiconductor device in accordance with still another embodiment. FIGS. 16A and 16B illustrate cross-sectional views showing a semiconductor device in accordance with still another embodiment. In FIGS. 16A and 16B, FIG. 16A illustrates a cross-sectional view showing an area taken along line Ih-Ih′ of FIG. 15A and an area taken along line IIh-IIh′ of FIG. 15A, and FIG. 16B illustrates a cross-sectional view showing an area taken along line IIIh-IIIh′ of FIG. 15A and an area taken along line IVh-IVh′ of FIG. 15A.

Referring to FIGS. 15A and 15B and FIGS. 16A and 16B, a semiconductor device 100b in accordance with still another embodiment may include an active region 140 on a semiconductor substrate 103, a gate structure 151b on the active region 140, and a first source/drain region 160 and a second source/drain region 163 in the active region 140 at both sides of the gate structure 151b.

The active region 140, as described in FIGS. 13A and 13B and FIGS. 14A and 14B, may include the first part 120 overlapped by the gate structure 151b, the second part 125 and the third part 130 facing each other with the first part 120 interposed therebetween. In addition, the first part 120 of the active region 140 may have a smaller width at a portion spaced apart from the second and third parts 125 and 130 than at a portion in contact with the second and third parts 125 and 130. The first part 120 of the active region 140 may include a first portion 109, and the second and third portions 112 and 113 having a greater width than the first portion 109 and facing each other with the first portion 109 interposed therebetween. The second portion 112 may be in contact with the second part 125, and the third portions 113 may be in contact with the third part 130.

In addition, as described in FIGS. 13A and 13B and FIGS. 14A and 14B, the first source/drain region 160 may be in the second part 125 of the active region 140, and the second source/drain region 163 may be in the third part 130 of the active region 140.

A channel region 172b may be defined in the first part 120 of the active region 140 between the first source/drain region 160 and the second source/drain region 163. The channel region 172b may have a greater width at a portion in contact with the first and second source/drain regions 160 and 163 than at a portion spaced apart from the first and second source/drain regions 160 and 163. In addition, the channel region 172b may include a first channel concentration area 178, and second channel concentration areas 175 facing each other with the first channel concentration area 178 interposed therebetween and having a higher channel impurity concentration than the first channel concentration area 178.

The second channel concentration areas 175 may be at ends of the first part 120 of the active region 140, and the first channel concentration area 178 may be between the second channel concentration areas 175. Here, the ends of the first part 120 of the active region 140 may be a portion adjacent to or in contact with the isolation region 106 and overlapped by the gate structure 151b.

The channel region 172b may have a greater width at a portion in contact with the first and second source/drain regions 160 and 163 than at a portion spaced apart from the first and second source/drain regions 160 and 163, and a high channel impurity concentration at the ends of the first part 120 may help improve hump characteristics of the transistor.

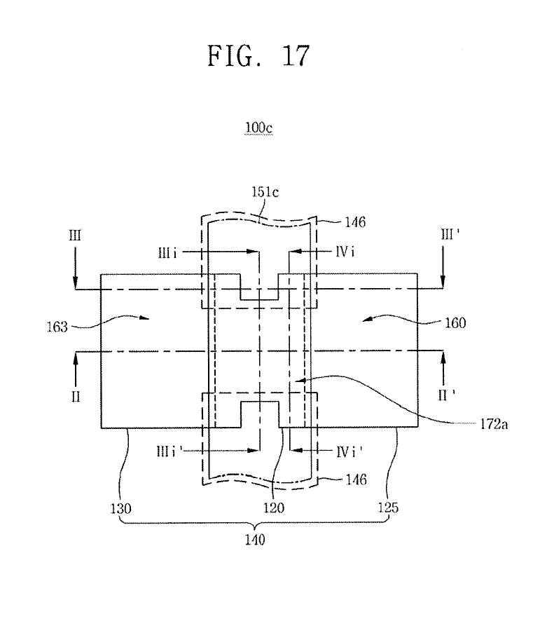

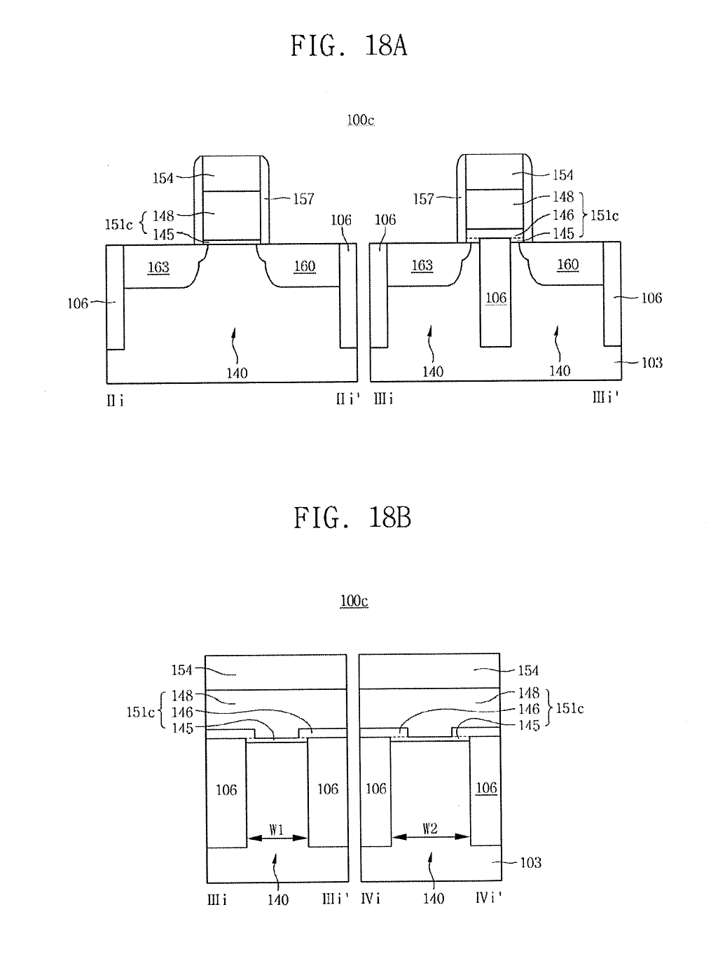

FIG. 17 illustrates a plan view showing a semiconductor device in accordance with still another embodiment. FIGS. 18A and 18B illustrate cross-sectional views showing a semiconductor device in accordance with still another embodiment. In FIGS. 18A and 18B, FIG. 18A illustrates a cross-sectional view showing an area taken along line Ii-Ii′ of FIG. 17 and an area taken along line IIi-IIi′ of FIG. 17, and FIG. 188 illustrates a cross-sectional view showing an area taken along line IIIi-IIIi′ of FIG. 17 and an area taken along line IVi-IVi′ of FIG. 17.

Referring to FIGS. 17, 18A, and 18B, a semiconductor device 100c in accordance with still another embodiment may include an active region 140 on a semiconductor substrate 103, a gate structure 151c on the active region 140, and a first source/drain region 160 and a second source/drain region 163 in the active region 140 at both sides of the gate structure 151c.

The active region 140, as described in FIGS. 13A and 13B and FIGS. 14A and 14B, may include the first part 120 overlapped by the gate structure 15c, the second part 125 and the third part 130 facing each other with the first part 120 interposed therebetween. In addition, the first part 120 of the active region 140 may have a smaller width at a portion spaced apart from the second and third parts 125 and 130 than at a portion in contact with the second and third parts 125 and 130. For example, the first part 120 of the active region 140 may include the first portion 109, and the second and third portions 112 and 113 having a greater width than the first portion 109 and facing each other with the first portion 109 interposed therebetween. In addition, as described in FIGS. 13A and 13B and FIGS. 14A and 14B, the first source/drain region 160 may be in the second part 125 of the active region 140, the second source/drain region 163 may be in the third part 130 of the active region 140, and the channel region 172a may be in the active region 140 between the first source/drain region 160 and the second source/drain region 163.

The gate structure 151c may include a gate dielectric 145 and a gate electrode 148 sequentially stacked on the active region 140. The gate electrode 148 may cross the active region 140. The gate dielectric 145 may be interposed between the active region 140 and the gate electrode 148.

Buffer dielectric patterns 146 may be under the gate electrode 148. The buffer dielectric patterns 146 may overlap ends of the first part 120 of the active region 140 adjacent to the isolation region 106. On the ends of the first part 120 of the active region 140 adjacent to the isolation region 106, the buffer dielectric patterns 146 may be interposed between the gate dielectric 145 and the gate electrode 148. Further, the buffer dielectric patterns 146 may extend between the gate electrode 148 and the isolation region 106.

The channel region 172a and the buffer dielectric patterns 146 may help improve hump characteristics of the transistor.

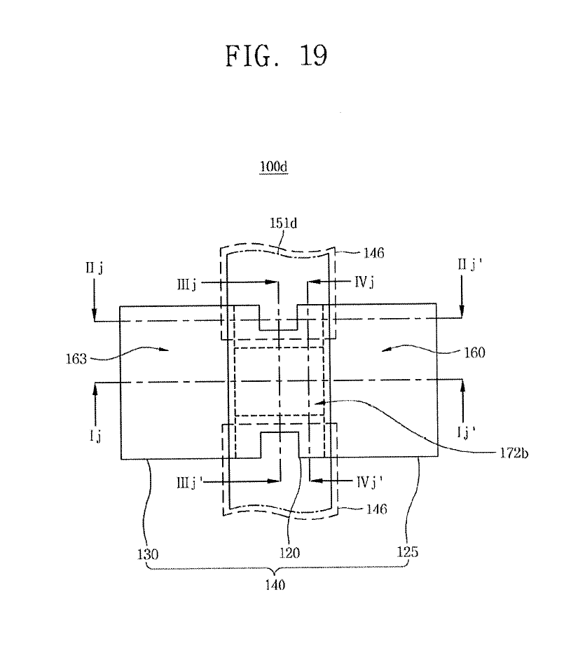

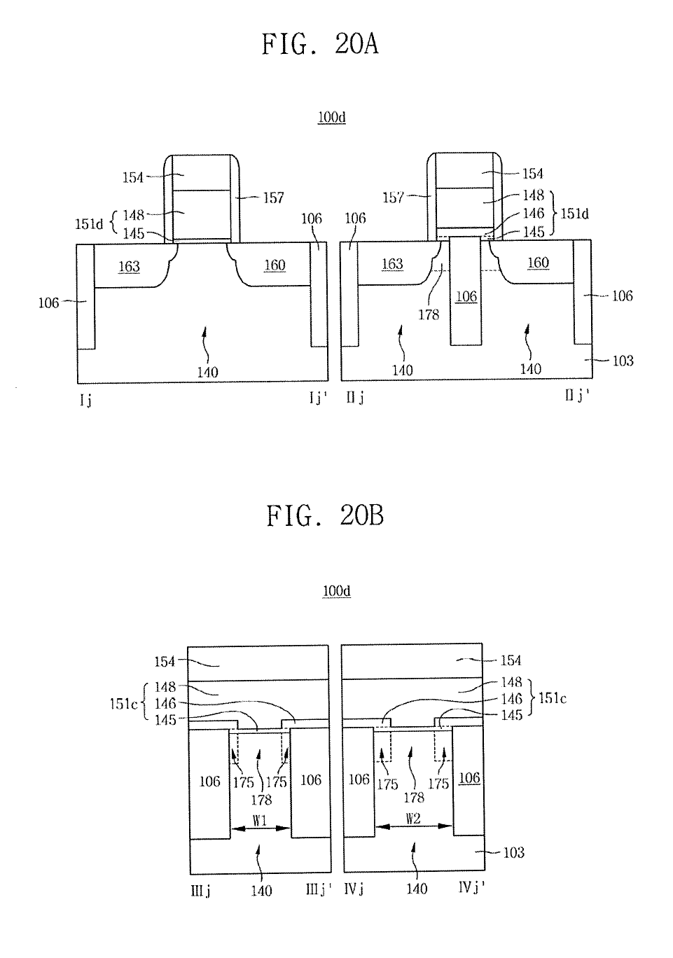

FIG. 19 illustrates a plan view showing a semiconductor device in accordance with still another embodiment, and FIGS. 20A and 20B illustrate cross-sectional views showing a semiconductor device in accordance with still another embodiment. In FIGS. 20A and 20B, FIG. 20A illustrates a cross-sectional view showing an area taken along line Ij-Ij′ of FIG. 19 and an area taken along line IIj-IIj′ of FIG. 19, and FIG. 208 illustrates a cross-sectional view showing an area taken along line IIIj-IIIj′ of FIG. 19 and an area taken along line IVj-IVj′ of FIG. 19.

Referring to FIGS. 19, 20A, and 20B, a semiconductor device 100d in accordance with still another embodiment may include an active region 140 on a semiconductor substrate 103, a gate structure 151d crossing the active region 140, a first source/drain region 160 and a second source/drain region 163 in the active region 140 disposed at both sides of the gate structure 151d.

The active region 140, as described in FIGS. 13A and 13B and FIGS. 14A and 14B, may include the first part 120 overlapped by the gate structure 151d, and the second part 125 and the third part 130 facing each other with the first part 120 therebetween. In addition, the first part 120 may include the first portion 109, and the second and third portions 112 and 113 having a greater width than the first portion 109 and facing each other with the first portion 109 therebetween.

In addition, as described in FIGS. 15A and 15B and FIGS. 16A and 16B, the first source/drain region 160 may be in the second part 125 of the active region 140, the second source/drain region 163 may be in the third part 130 of the active region 140, and the channel region 172b may be in the active region 140 between the first source/drain region 160 and the second source/drain region 163.

The channel region 172b may have a greater width at a portion in contact with the first source/drain region 160 and the second source/drain region 163 than at a portion spaced apart from the first source/drain region 160 and the second source/drain region 163. In addition, the channel region 172b, as described in FIGS. 15A and 15B and FIGS. 16A and 163, may include the second channel concentration areas 175, and the first channel concentration area 178 between the second channel concentration areas 175.

The gate structure 151d may include a gate dielectric 145 and a gate electrode 148 sequentially stacked on the active region 140. The gate electrode 148 may cross the active region 140. The gate dielectric 145 may be between the active region 140 and the gate electrode 148.

The buffer dielectric patterns 146 as shown in FIGS. 17, 18A, and 18B, may be under the gate electrode 148. The buffer dielectric patterns 146 may overlap ends of the first part 120 of the active region 140 adjacent to the isolation region 106, and may be between the gate dielectric 145 and the gate electrode 148. Further, the buffer dielectric patterns 146 may extend between the gate electrode 148 and the isolation region 106.

The channel region 172b and the buffer dielectric patterns 146 may help improve hump characteristics of the transistor.

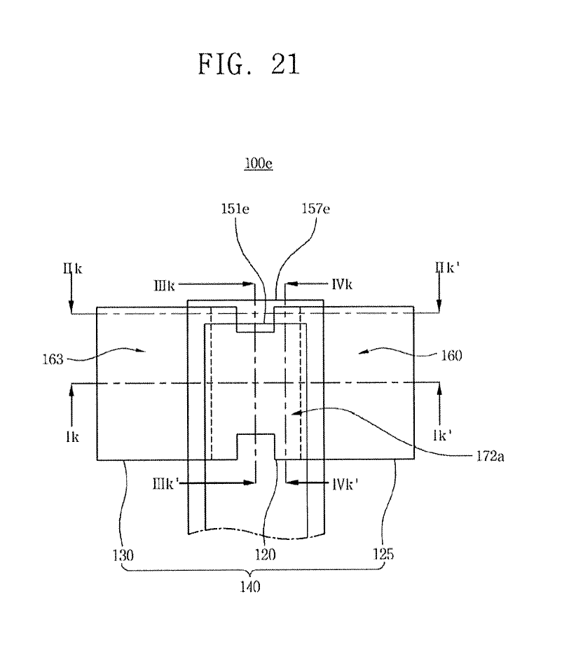

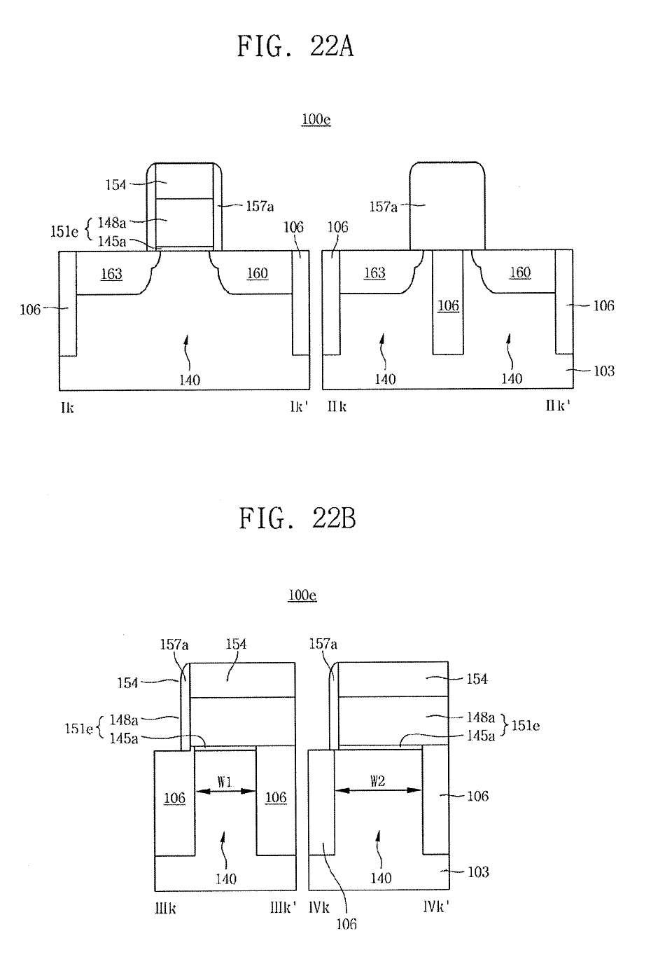

FIG. 21 illustrates a plan view showing a semiconductor device in accordance with still another embodiment, and FIGS. 22A and 22B illustrate cross-sectional views showing a semiconductor device in accordance with still another embodiment. In FIGS. 22A and 22B, FIG. 22A illustrates a cross-sectional view showing an area taken along line Ik-Ik′ of FIG. 21 and an area taken along line Ilk-IIk′ of FIG. 21, and FIG. 22B illustrates a cross-sectional view showing an area taken along line IIIk-IIIk′ of FIG. 21 and an area taken along line IVk-IVk′ of FIG. 21.

Referring to FIGS. 21, 22A, and 22B, a semiconductor device 100e in accordance with still another embodiment may include an active region 140 on a semiconductor substrate 103, a gate structure 151e on the active region 140, and a first source/drain region 160 and a second source/drain region 163 in the active region 140 disposed at both sides of the gate structure 151e.

The active region 140, as described in FIGS. 13A and 13B and FIGS. 14A and 14B, may include the first part 120, and the second part 125 and the third part 130 facing each other with the first part 120 interposed therebetween. In addition, the first part 120 may include a first portion 109, and the second and third portions 112 and 113 having a greater width than the first portion 109 and facing each other with the first portion 109 interposed therebetween.

In addition, as described in FIGS. 13A and 13B and FIGS. 14A and 14B, the first source/drain region 160 may be in the second part 125 of the active region 140, the second source/drain region 163 may be in the third part 130 of the active region 140, and the channel region 172a may be in the active region 140 between the first source/drain region 160 and the second source/drain region 163.

The gate structure 151e may include a gate dielectric 145a and a gate electrode 148a. The gate dielectric 145a may be between the gate electrode 148a and the active region 140.

A gate capping pattern 154 (self-aligned with the gate electrode 148a) may be on the gate electrode 148a. A gate spacer 157a may be on side surfaces of the gate structure 151e and gate capping pattern 154.

The gate electrode 148a may have a portion overlapping the active region 140 and extending onto the isolation region 106. The gate dielectric 145 may be between the gate electrode 148a and the active region 140. A gate capping pattern 154 (self-aligned with the gate electrode 148a) may be on the gate electrode 148a. A gate spacer 157a may be on side surfaces of the gate structure 151e and the gate capping pattern 154.

The gate electrode 148 may cover the first portion 109 of the active region 140, and may partially cover the second and third portions 112 and 113 of the active region 140.

One end of the second portion 112 of the active region 140 may not be overlapped by the gate electrode 148a. In an implementation, both ends of the second and third portions 112 and 113 of the active region 140 may be ends that are adjacent to the isolation region 106. In addition, an end that is not overlapped by the gate electrode 148a among the ends of the second and third portions 112 and 113 of the active region 140, may be overlapped by the gate spacer 157a.

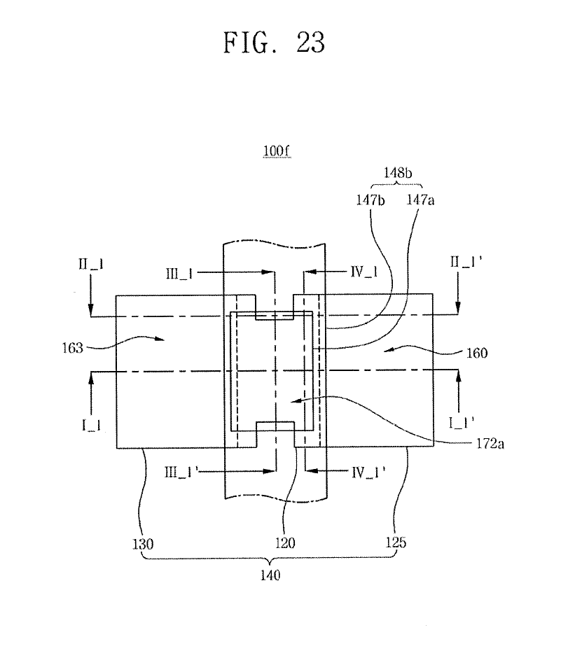

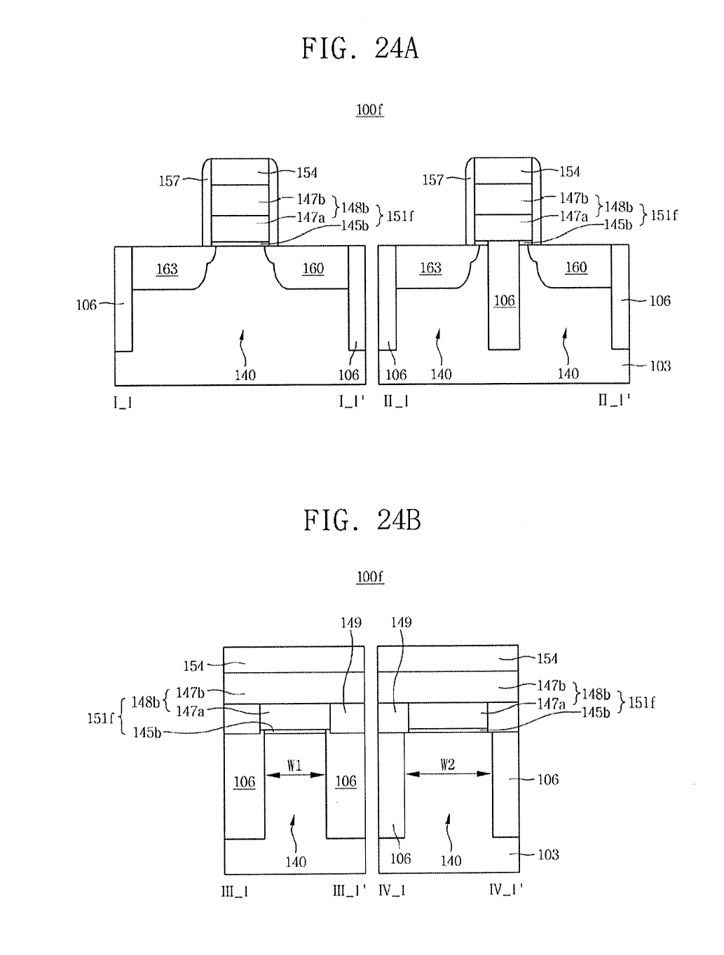

FIG. 23 illustrates a plan view showing a semiconductor device in accordance with still another embodiment, and FIGS. 24A and 24B illustrate cross-sectional views showing a semiconductor device in accordance with still another embodiment. In FIGS. 24A and 2413, FIG. 24A illustrates a cross-sectional view showing an area taken along line II-II′ of FIG. 23 and an area taken along line III-III′ of FIG. 23, and FIG. 24B illustrates a cross-sectional view showing an area taken along line IIII-IIII′ of FIG. 23 and an area taken along line IVI-IVI′ of FIG. 23.

Referring to FIGS. 23, 24A, and 24B, a semiconductor device 100f in accordance with still another embodiment may include an active region 140 on a semiconductor substrate 103, a gate structure 151f on the active region 140, and a first source/drain region 160 and a second source/drain region 163 in the active region 140 disposed at both sides of the gate structure 151f. The active region 140, as described in FIGS. 13A and 13B and FIGS. 14A and 148, may include the first part 120, and the second part 125 and the third part 130 facing each other with the first part 120 interposed therebetween.

In addition, the first part 120 of the active region 140 may have a smaller width at a portion spaced apart from the second and third parts 125 and 130 than at a portion in contact with the second and third parts 125 and 130. For example, the first part 120 of the active region 140, as described in FIG. 138, may include the first portion 109, and the second and third portions 112 and 113 having a width W2 greater than a width W1 of the first portion 109 and facing each other with the first portion 109 interposed therebetween.

As described in FIGS. 13A and 13B and FIGS. 14A and 148, the first source/drain region 160 may be formed in the second part 125 of the active region 140, the second source/drain region 163 may be formed in the third part 130 of the active region 140, and the channel region 172a may be formed in the active region 140 between the first source/drain region 160 and the second source/drain region 163.

The gate structure 151f may include a gate dielectric 145b and a gate electrode 148b. A gate capping pattern 154 self-aligned with the gate electrode 148b may be disposed on the gate electrode 148b. A gate spacer 157 may be on side surfaces of the gate structure 151f and the gate capping pattern 154.

The gate electrode 148b may include a lower gate electrode 147a and an upper gate electrode 147b on the lower gate electrode 147a. The gate dielectric 145b may be between the lower gate electrode 147a and the active region 140.

The lower gate electrode 147a may cover the first portion 109, and may partially cover the second and third portions 112 and 113. Accordingly, the lower gate electrode 147a may not overlap both ends of the second and third portions 112 and 113 of the first part 120 of the active region 140. Here, the ends of the second and third portions 112 and 113 may be ends that are adjacent to the isolation region 106.

The upper gate electrode 1476 may overlap the lower gate electrode 147a, may cross over the active region 140, and may extend onto the isolation region 106. An insulating pattern 149 may be under the upper gate electrode 147b. The insulating pattern 149 may be between the upper gate electrode 147b and the isolation region 106, and between the ends of the second and third portions 112 and 113 that are not overlapped by the lower gate electrode 147a, and the upper gate electrode 147b. The insulating pattern 149 may be formed of an insulating material, such as silicon oxide or silicon nitride.

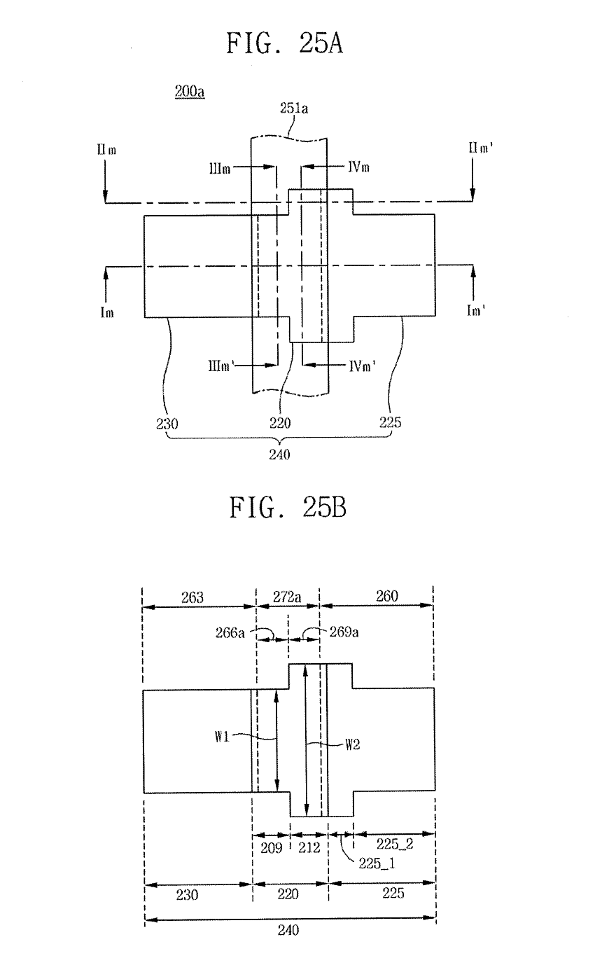

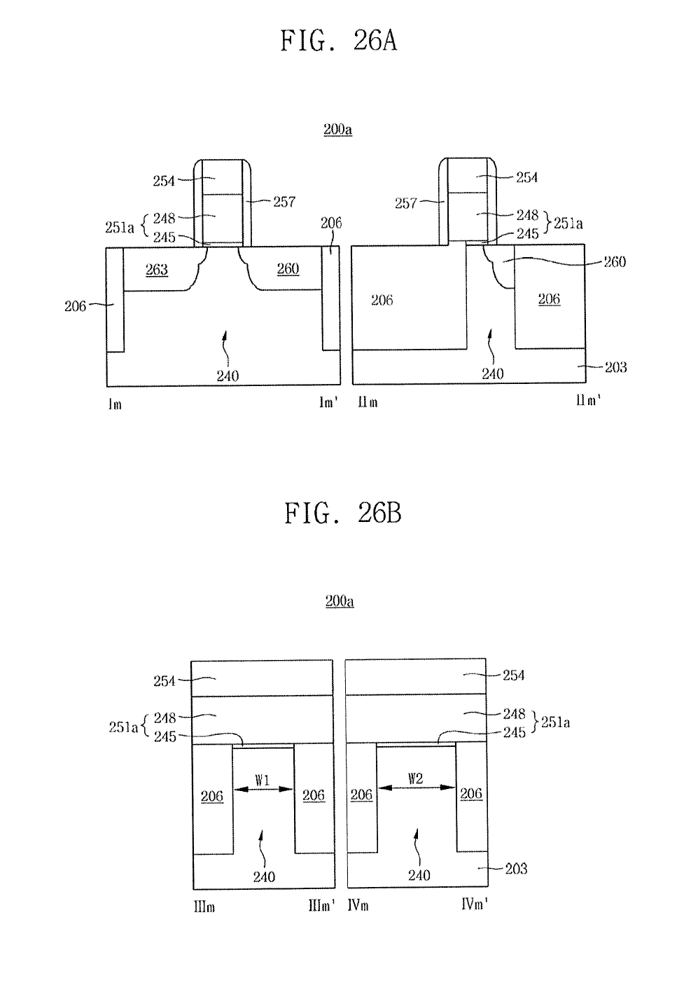

FIG. 25A illustrates a plan view showing a semiconductor device in accordance with still another embodiment, FIG. 25B illustrates a plan view showing some elements of the semiconductor device in accordance with still another embodiment, and FIGS. 26A and 26B are cross-sectional views showing a semiconductor device in accordance with still another embodiment. In FIGS. 26A and 26B, FIG. 26A illustrates a cross-sectional view showing an area taken along line Im-Im′ of FIG. 25A and an area taken along line IIm-IIm′ of FIG. 25A, and FIG. 26B illustrates a cross-sectional view showing an area taken along line IIIm-IIIm′ of FIG. 25A and an area taken along line IVm-IVm′ of FIG. 25A.

Referring to FIGS. 25A and 25B and 26A and 26B, a semiconductor device 200a in accordance with still another embodiment may include an active region 240 on a semiconductor substrate 203, a gate structure 251a on the active region 240, and a source region 263 and a drain region 260 formed in the active region 240 disposed at sides of the gate structure 251a. The active region 240 may be defined by an isolation region 206 formed in the semiconductor substrate 203.

The gate structure 251a may include a gate dielectric 245 and a gate electrode 248 sequentially stacked on the active region 240. The gate electrode 248 of the gate structure 251a may cross the active region 240.

A gate capping pattern 254 may be on the gate electrode 248. The gate capping pattern 254 may be formed of an insulating material, such as silicon oxide or silicon nitride. A gate spacer 257 may be on side surfaces of the gate structure 251a and the gate capping pattern 254. The gate spacer 257 may be formed of an insulating material, such as silicon nitride or a high-k dielectric material.

The active region 240 may include a first part 220 overlapped by the gate structure 251a, and a second part 225 and a third part 230 facing each other with the first part 220 interposed therebetween.

The first part 220 of the active region 240 may have a greater width at a portion in contact with or adjacent to the second part 225 than at a portion spaced apart from the second part 225. In the active region 240, the first part 220 may include a first portion 209 and a second portion 212. The first portion 209 may have a first width W1, and the second portion 212 may have a second width W2 greater than the first width W1. The second portion 212 may be in contact with the second part 225, and the first portion 209 may be in contact with the third part 230.

The second part 225 of the active region 240 may have a greater width at a portion in contact with the first part 220 than at a portion spaced apart from the first part 220. In the active region 240, the second part 225 may include a portion 225_1 having the second width W2, and a portion 225_2 having a width smaller than the second width W2. In the second part 225 of the active region 240, the portion 225_1 having the second width W2 may have the same width as the second portion 212 of the first part 220, and may be in contact with the second portion 212 of the first part 220.

The source region 263 and the drain region 260 may be in the active region 240 adjacent to sides of the gate structure 251a. The active region between the source region 263 and the drain region 260 may be defined as a channel region 272a. The drain region 260 may be in the second part 225 of the active region 240. The source region 263 may be in the third part 230 of the active region 240. The channel region 272a may be in the first part 220 of the active region 240. The channel region 272a may include a first channel region 266a adjacent to the source region 263, and a second channel region 269a adjacent to the drain region 260. The first channel region 266a may be in the first portion 209 of the active region 240, and the second channel region 269a may be formed in the second portion 212 of the active region 240. The first channel region 266a may have a first width W1, and the second channel region 269a may have a second width W2 greater than the first width W1. Here, the widths of the first and second channel regions 266a and 269a may be distances between the first side surface and a second side surface, which face each other, of the first part 220 adjacent to the isolation region 206. The drain region 260 may have the same width as the second channel region 269a, e.g., the second width W2, at a portion adjacent or proximate to the channel region 272a, and width W1 smaller than the second width W2 at a portion far from or distal to the channel region 272a. The channel region 272a may help improve hump characteristics of the transistor.

In an implementation, at least one of at least one of the second part 225 or the third part 230 may have stepped shape including at least one discontinuous change in width therein.

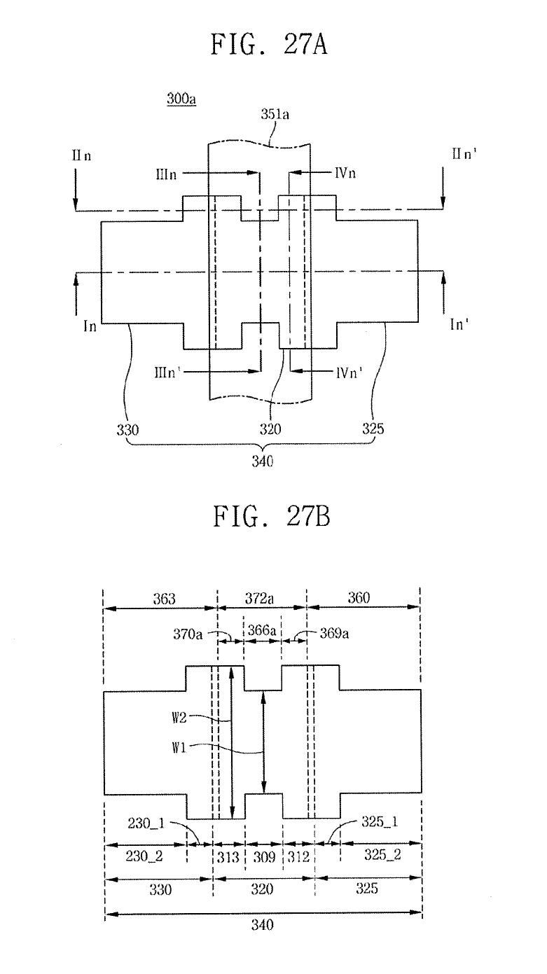

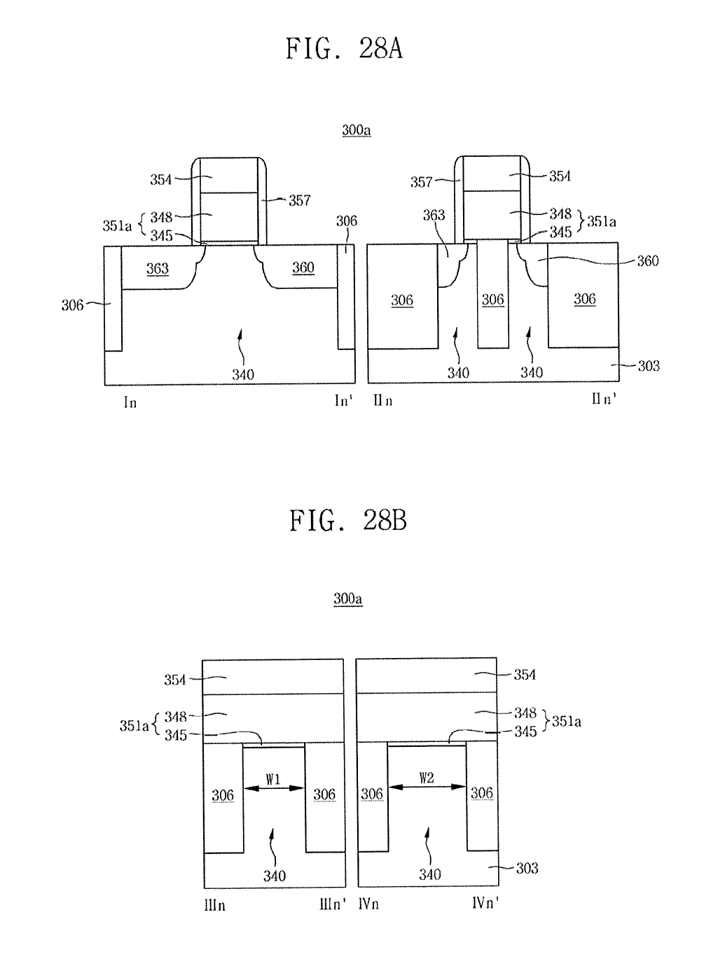

FIG. 27A illustrates a plan view showing a semiconductor device in accordance with still another embodiment, FIG. 27B illustrates a plan view showing some elements of the semiconductor device in accordance with still another embodiment, and FIGS. 28A and 28B illustrate cross-sectional views showing a semiconductor device in accordance with still another embodiment. In FIGS. 28A and 28B, FIG. 28A illustrates a cross-sectional view showing an area taken along line In-In′ of FIG. 27A and an area taken along line IIn-IIn′ of FIG. 27A, and FIG. 28B illustrates a cross-sectional view showing an area taken along line IIIn-IIIn′ of FIG. 27A and an area taken along line IVn-IVn′ of FIG. 27A.

Referring to FIGS. 27A and 27B and FIGS. 28A and 28B, a semiconductor device 300a in accordance with still another embodiment may include an active region 340 on a semiconductor substrate 303, a gate structure 351a on the active region 340, and a first source/drain region 360 and a second source/drain region 363 in the active region 340 at sides of the gate structure 351a. The active region 340 may be defined by an isolation region 306 in the semiconductor substrate 303.

The gate structure 351a may include a gate dielectric 345 and a gate electrode 348 sequentially stacked on the active region 340. The gate electrode 348 of the gate structure 351a may cross the active region 340.

A gate capping pattern 354 may be on the gate electrode 348. The gate capping pattern 354 may be formed of an insulating material, such as silicon oxide or silicon nitride. A gate spacer 357 may be on side surfaces of the gate structure 351a and the gate capping pattern 354. The gate spacer 357 may be formed of an insulating material, such as silicon nitride, or a high-k dielectric material.

The active region 340 may include a first part 320 overlapped by the gate structure 351a, and a second part 325 and a third part 330 facing each other with the first part 320 therebetween.

The first part 320 of the active region 340 may have a greater width at a portion in contact with the second and third parts 325 and 330 than at a portion spaced apart from the second and third parts 325 and 330. In the active region 340, the first part 320 may include a first portion 309, and second and third portions 312 and 313 at sides of the first portion 309. The first portion 309 may have a first width W1, and the second and third portions 312 and 313 may each have a second width W2 greater than the first width W1. In the active region 340, the second part 325 may be in contact with the second portion 312, and the third part 330 may be in contact with the third portion 313.

In the active region 340, the second part 325 may have the same width as the second portion 312 at a portion 325_1 in contact with the second portion 312, and a smaller width than the second portion 312 at a portion 325_2 spaced apart from the second portion 312.

In the active region 340, the third part 330 may have the same width as the third portion 313 at a portion 330_1 in contact with the third portion 313, and a smaller width than the third portion 313 at a portion 330_2 spaced apart from the third portion 313.

The first source/drain region 360 may be in the second part 325 of the active region 340, the second source/drain region 363 may be in the third part 330 of the active region 340, and a channel region 372a may be in the first part 320 of the active region 340.

The channel region 372a may have a first channel width W1 at a portion 366a spaced apart from the first and second source/drain regions 360 and 363, and a second channel width W2 greater than the first channel width W1 at a portion 369a in contact with the first source/drain region 360 and at a portion 370a in contact with the second source/drain region 363.

Accordingly, the channel region 372a (having a relatively greater channel width at a portion in contact with the first and second source/drain regions 360 and 363) may help improve hump characteristics of the transistor.

In an implementation, a semiconductor device in accordance with an embodiment may include a finFET device. Hereinafter, other embodiments of a semiconductor device including a finFET device capable of improving the corner effect of the transistor will be described.

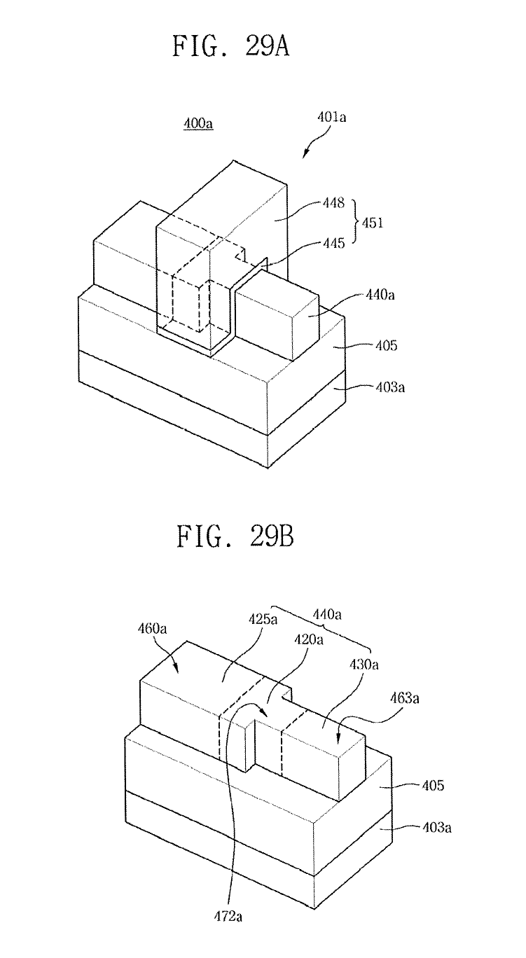

FIG. 29A illustrates a perspective view showing a semiconductor device in accordance with still another embodiment, and FIG. 29B illustrates a perspective view for describing some elements of a semiconductor device in accordance with still another embodiment.

Referring to FIGS. 29A and 29B, a semiconductor device 400a in accordance with still another embodiment may include a fin-type field effect transistor (finFET) 401a. The semiconductor device 400a may include an active region 440a on a substrate 403a, an insulating layer 405 between the active region 440a and the substrate 403a, a gate structure 451 on the active region 440a, and a source region 463a and a drain region 460a in the active region 440a disposed at both sides of the gate structure 451.

The substrate 403a may be a silicon substrate. The insulating layer 405 may be formed of an insulating material such as silicon oxide.

The active region 440a may be an active pattern or semiconductor pattern spaced apart from the substrate 403a. For example, the active region 440a may be a semiconductor pattern formed of a silicon material. In an implementation, the active region 440a may be a compound semiconductor pattern including at least two elements of Group III, Group IV, and Group V elements of the periodic table.

The gate structure 451 may cross the active region 440a, and may surround an upper surface of the active region 440a and two opposite side surfaces of the active region 440a.

The gate structure 451 may include a gate dielectric 445 and a gate electrode 448. The gate electrode 448 may surround upper and side surfaces of the active region 440a, and may extend onto the insulating layer 405. The gate dielectric 445 may be between the active region 440a and the gate electrode 448.

In an implementation, the gate dielectric 445 may include a layer formed using a deposition (e.g., ALD or CVD) method. The gate dielectric 445 may be between the active region 440a and the gate electrode 448, and may extend between the insulating layer 405 and the gate electrode 448.

The active region 440a may include a first part 420a, and a second part 425a and a third part 430a facing each other with the first part 420a therebetween. The first part 420a of the active region 440a may be a portion overlapped by the gate structure 451. Accordingly, the gate structure 451 may surround an upper surface of the first part 420a of the active region 440a, and two opposite side surfaces of the first part 420a of the active region 440a. A plan view of the active region 440a may be the same as the plan view of the active region 40 described in FIGS. 1A and 1B and FIGS. 2A and 2B. In a plan view, the active region 440a may include a first portion having a first width, and a second portion having a second width greater than the first width, like the active region 40 described in FIGS. 1A and 1B and FIGS. 2A and 2B.

The drain region 460a may be in the second part 425a of the active region 440a, and the source region 463a may be in the third part 430a of the active region 440a. A channel region 472a of the finFET 401a may be formed in the first part 420a of the active region 440a between the source region 463a and the drain region 460a.

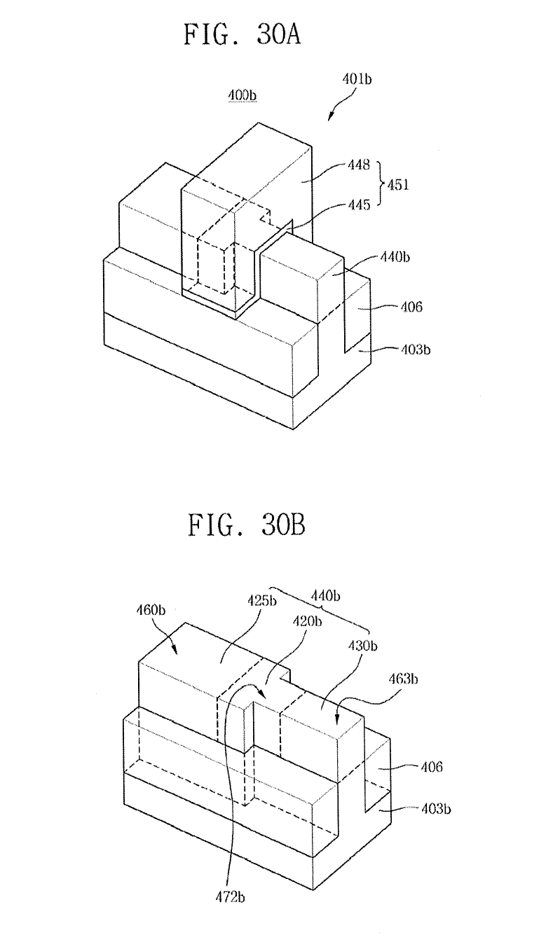

FIG. 30A illustrates a perspective view showing a semiconductor device in accordance with still another embodiment, and FIG. 30B illustrates a perspective view for describing some elements of a semiconductor device in accordance with still another embodiment.

Referring to FIGS. 30A and 30B, a semiconductor device 400b in accordance with still another embodiment may include a finFET 401b. The semiconductor device 400b may include an active region 440b on a substrate 403b, a gate structure 451 on the active region 440b, and a source region 463b and a drain region 460b in the active region 440b disposed at sides of the gate structure 451. The substrate 403b may be a semiconductor substrate formed of silicon or the like.

The active region 440b may have a shape of a fin protruding from the substrate 403b. An isolation region 406 may be at a part of a side surface of the active region 440b. The isolation region 406 may be formed using a shallow trench isolation process, and formed of an insulating material.

The gate structure 451 may cross the active region 440b, and may surround an upper surface of the active region 440b and two opposite upper side surfaces of the active region 440b. Lower side surfaces of the active region 440b (under the gate structure 45I) may be covered by the isolation region 406.

The gate structure 451 may include a gate dielectric 445 and a gate electrode 448. The gate electrode 448 may surround upper and side surfaces of the active region 440b and may extend onto the insulating layer 405. The gate dielectric 445 may be between the active region 440b and the gate electrode 448. The active region 440b may include a first part 420b, and a second part 425b and a third part 430b facing each other with the first part 420b interposed therebetween. The first part 420b of the active region 440b may be a portion overlapped by the gate structure 451. Accordingly, the gate structure 451 may surround an upper surface of the first part 420b of the active region 440b, and two opposite side surfaces of the first part 420b of the active region 440b.

A plan view of the active region 440b may be the same as that of the active region 40 described in FIGS. 1A and 1B and FIGS. 2A and 2B. In a plan view, the active region 440b may include a first portion having a first width, and a second portion having a second width greater than the first width, like the active region 40 described in FIGS. 1A and 1B and FIGS. 2A and 2B.

The drain region 460b may be in the second part 425b of the active region 440b, and the source region 463b may be in the third part 430b of the active region 440b. A channel region 472b of the finFET 401b may be in the first part 420b of the active region 440b between the source region 463b and the drain region 460b.

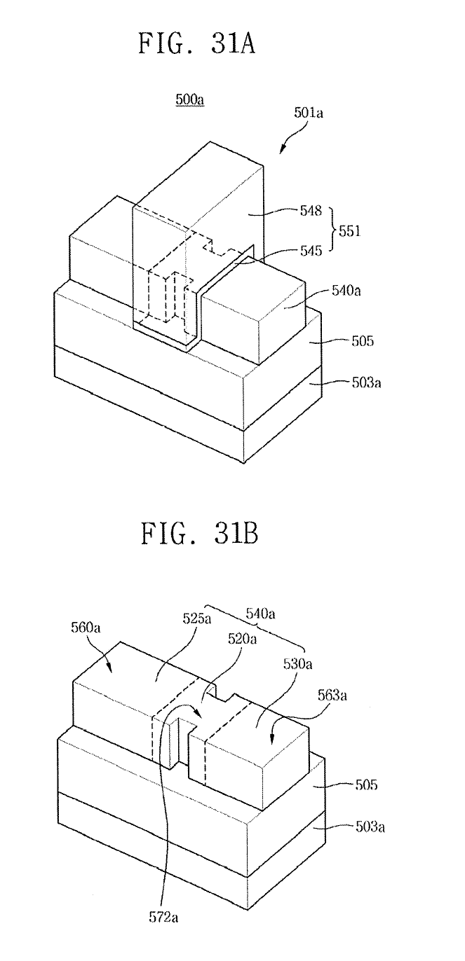

FIG. 31A illustrates a perspective view showing a semiconductor device in accordance with still another embodiment, and FIG. 31B illustrates a perspective view for describing some elements of a semiconductor device in accordance with still another embodiment.

Referring to FIGS. 31A and 31B, a semiconductor device 500a in accordance with still another embodiment may include a finFET 50a. The semiconductor device 500a may include an active region 540a on a substrate 503a, an insulating layer 505 between the active region 540a and the substrate 503a, a gate structure 551 on the active region 540a, and a first source/drain region 560a and a second source/drain region 563a in the active region 540a disposed at both sides of the gate structure 551. The substrate 503a may be a semiconductor substrate.

The active region 540a may be an active pattern or a semiconductor pattern spaced apart from the substrate 503a. The gate structure 551 may cross the active region 540a, and may surround an upper surface of the active region 540a and two opposite side surfaces of the active region 540a.

The gate structure 551, like the gate structure 451 described in FIG. 29A, may include a gate dielectric 545, and a gate electrode 548 on the gate dielectric 545. The active region 540a may include a first part 520a, and a second part 525a and a third part 530a facing each other with the first part 520a interposed therebetween. The first part 520a of the active region 540a may include a portion overlapped by the gate structure 551. Accordingly, the gate structure 551 may surround an upper surface of the first part 520a of the active region 540a, and two opposite side surfaces of the first part 520a of the active region 540a.

A plan view of the active region 540a may be the same as that of the active region 140 described in FIGS. 13A and 13B and FIGS. 14A and 14B. In a plan view, the first part 520a of the active region 540a may have a first portion having a first width, and second and third portions having a second width greater than the first width and facing each other with the first portion interposed therebetween, like the active region 140 described in FIGS. 13A and 13B and FIGS. 14A and 14B.

The first source/drain region 560a may be in the second part 525a of the active region 540a, and the second source/drain region 563a may be in the third part 530a of the active region 540a. A channel region 572a of the finFET 501a may be in the first part 520a of the active region 540a between the first source/drain region 560a and the second source/drain region 563a.

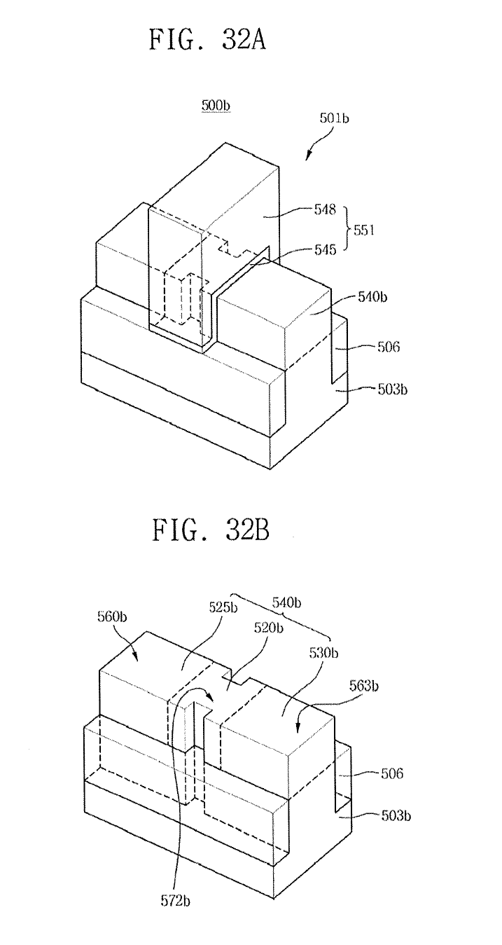

FIG. 32A illustrates a perspective view showing a semiconductor device in accordance with still another embodiment, and FIG. 32B illustrates a perspective view for describing some elements of a semiconductor device in accordance with still another embodiment.

Referring to FIGS. 32A and 32B, a semiconductor device 500b in accordance with still another embodiment may include a finFET 50b. The semiconductor device 500b may include an active region 540b on a substrate 503b, a gate structure 551 of the active region 540b, and a first source/drain region 560b and a second source/drain region 563b in the active region 540b at sides of the gate structure 551. The substrate 503b may be a semiconductor substrate formed of a material such as silicon.

The active region 540b may have a shape of a fin protruding from the substrate 503b. An isolation region 506 may be on a part of a side surface of the active region 540b. The isolation region 506 may be formed using a shallow trench isolation process, and formed of an insulating material.

The gate structure 551 may cross the active region 540b, and may surround an upper surface of the active region 540b and two opposite upper side surfaces of the active region 540b. Lower side surfaces of the active region 540b (under the gate structure 551) may be covered by the isolation region 506.

The gate structure 551, like the gate structure 451 described in FIG. 29A, may include a gate dielectric 545, and a gate electrode 548 on the gate dielectric 545.

The active region 540b may include a first part 520b, and a second part 525b and a third part 530b facing each other with the first part 520b interposed therebetween. The first part 520b of the active region 540b may be a portion overlapped by the gate structure 551. Accordingly, the gate structure 551 may surround an upper surface of the first part 520b of the active region 540b, and two opposite side surfaces of the first part 520b of the active region 540b. A plan view of the active region 540b may be the same as that of the active region 140 described in FIGS. 13A and 13B and FIGS. 14A and 14B. In a plan view, the first part 520b of the active region 540b, like the active region 140 described in FIGS. 13A and 13B and FIGS. 14A and 14B, may have a first portion having a first width, and second and third portions having a second width greater than the first width and facing each other with the first portion therebetween.

The first source/drain region 560b may be in the second part 525b of the active region 540b, and the second source/drain region 5636 may be in the third part 530b of the active region 540b. A channel region 572b of the finFET 501b may be in the first part 520b of the active region 540b between the first source/drain region 560b and the second source/drain region 563b.

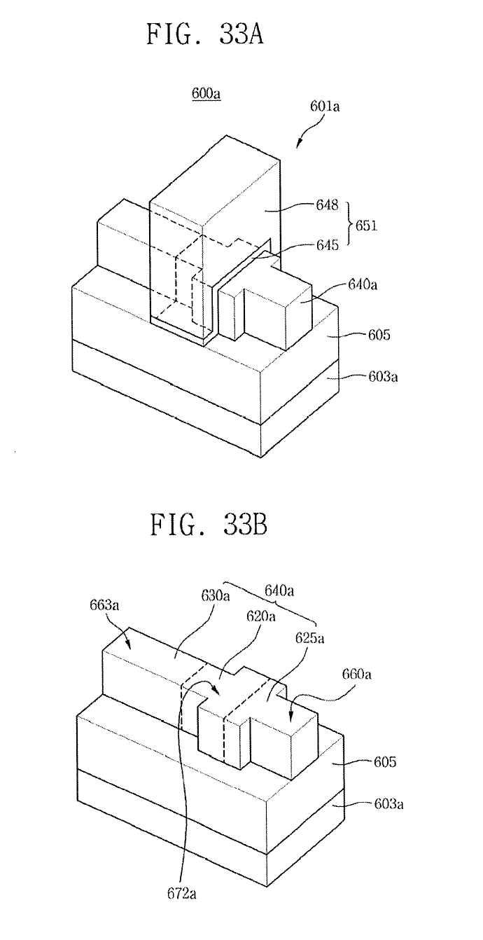

FIG. 33A illustrates a perspective view showing a semiconductor device in accordance with still another embodiment, and FIG. 33B illustrates a perspective view for describing some elements of a semiconductor device in accordance with still another embodiment.

Referring to FIGS. 33A and 33B, a semiconductor device 600a in accordance with still another embodiment may include a finFET 601a. The semiconductor device 600a may include an active region 640a on a substrate 603a, an insulating layer 605 between the active region 640a and the substrate 603a, a gate structure 651 on the active region 640a, and a source region 663a and a drain region 660a in the active region 640a disposed at sides of the gate structure 651. The substrate 603a may be a semiconductor substrate.

The active region 640a may be an active pattern or a semiconductor pattern spaced apart from the substrate 603a. The gate structure 651 may cross the active region 640a, and may surround an upper surface of the active region 640a, and two opposite side surfaces of the active region 640a. The gate structure 651, like the gate structure 451 described in FIG. 29A, may include a gate dielectric 645 and a gate electrode 648 on the gate dielectric 645.

The active region 640a may include a first part 620a, and a second part 625a and a third part 630a facing each other with the first part 620a therebetween. The first part 620a of the active region 640a may be a portion overlapped by the gate structure 651. Accordingly, the gate structure 651 may surround an upper surface of the first part 620a of the active region 640a, and two opposite side surfaces of the first part 620a of the active region 640a. A plan view of the active region 640a may be the same as that of the active region 240 described in FIGS. 25A and 25B and FIGS. 26A and 268. In a plan view, the first part 620u of the active region 640a, like the first part 220 of the active region 240 described in FIGS. 25A and 25B and FIGS. 26A and 268, may include portions having different widths. In addition, the second part 625a of the active region 640a, like the second part 225 of the active region 240 described in FIGS. 25A and 25B and FIGS. 26A and 26B, may include portions having different widths.

The drain region 660a may be in the second part 625a of the active region 640a, and the source region 663a may be in the third part 630a of the active region 640a. A channel region 672a of the finFET 601a may be in the first part 620a of the active region 640a between the drain region 660a and the source region 663a.

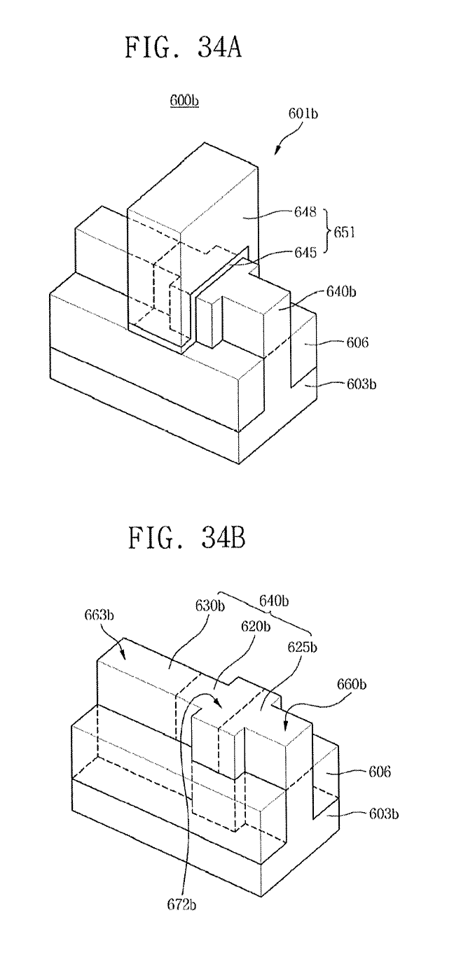

FIG. 34A illustrates a perspective view showing a semiconductor device in accordance with still another embodiment, and FIG. 348 illustrates a perspective view for describing some elements of a semiconductor device in accordance with still another embodiment.

Referring to FIGS. 34A and 348, a semiconductor device 600b in accordance with still another embodiment may include a finFET 601b. The semiconductor device 600b may include an active region 640b on a substrate 603b, a gate structure 651 on the active region 640b, and a drain region 660b and a source region 663b in the active region 640b at sides of the gate structure 651. The substrate 603b may be a semiconductor substrate formed of a material such as silicon. The active region 640b may have a shape of a fin protruding from the substrate 603b. An isolation region 606 may be on a part of a side surface of the active region 640b. The isolation region 606 may be formed using a shallow trench isolation process, and may be formed of an insulating material. The gate structure 651 may cross the active region 640b, and may surround an upper surface of the active region 640b and two opposite upper side surfaces of the active region 640b. Lower side surfaces of the active region 640b (under the gate structure 651) may be covered by the isolation region 606.

The gate structure 651, like the gate structure 451 described in FIG. 29A, may include a gate dielectric 645 and a gate electrode 648 disposed on the gate dielectric 645.

The active region 640b may include a first part 620b, and a second part 625b and a third part 630b facing each other with the first part 620b therebetween. The first part 620b of the active region 640b may be a portion overlapped by the gate structure 651. Accordingly, the gate structure 651 may surround an upper surface of the first part 620b of the active region 640b, and two opposite side surfaces of the first part 620b of the active region 640b. A plan view of the active region 640b may be the same as that of the active region 640a described in FIGS. 33A and 3313. The drain region 660b may be in the second part 625b of the active region 640b, and the source region 663b may be in the third part 630b of the active region 640b. A channel region 672b of the finFET 601b may be in the first part 620b of the active region 640b between the drain region 660b and the source region 663b.

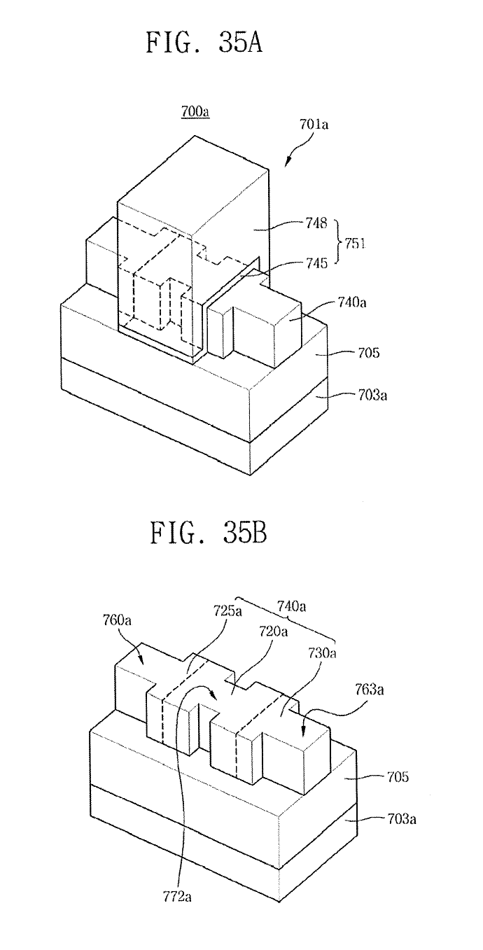

FIG. 35A illustrates a perspective view showing a semiconductor device in accordance with still another embodiment, and FIG. 35B illustrates a perspective view for describing some elements of a semiconductor device in accordance with still another embodiment.

Referring to FIGS. 35A and 35B, a semiconductor device 700a in accordance with still another embodiment may include a finFET 701a. The semiconductor device 700a may include an active region 740a on a substrate 703a, an insulating layer 705 between the active region 740a and the substrate 703a, a gate structure 751 on the active region 740a, and a first source/drain region 760a and a second source/drain region 763a in the active region 740a at sides of the gate structure 751. The substrate 703a may be a semiconductor substrate. The active region 740a may be an active pattern or semiconductor pattern spaced apart from the substrate 703a.

The gate structure 751 may cross the active region 740a and may surround an upper surface of the active region 740a, and two opposite side surfaces of the active region 740a. The gate structure 751, like the gate structure 451 described in FIG. 29A, may include a gate dielectric 745 and a gate electrode 748 on the gate dielectric 745.

The active region 740a may include a first part 720a, and a second part 725a and a third part 730a facing each other with the first part 720a interposed therebetween. The first part 720a of the active region 740a may be a portion overlapped by the gate structure 751. Accordingly, the gate structure 751 may surround an upper surface of the first part 720a of the active region 740a, and two opposite side surfaces of the first part 720a of the active region 740a. A plan view of the active region 740a may be the same as that of the active region 340 described in FIGS. 27A and 27B and FIGS. 28A and 28B. In a plan view, the first part 720a of the active region 740a, like the first part 320 of the active region 340 described in FIGS. 27A and 27B and FIGS. 28A and 28B, may include portions having different widths. In addition, in a plan view, the second part 725a and the third part 730a of the active region 740a, like the second part 325 and the third part 330 of the active region 340 described in FIGS. 27A and 27B and FIGS. 28A and 28B, may include portions having different widths.

The first source/drain region 760a may be in the second part 725a of the active region 740a, and the second source/drain region 763a may be in third part 730a of the active region 740a. A channel region 772a of the finFET 701a may be in the first part 720a of the active region 740a between the first source/drain region 760a and the second source/drain region 763a.

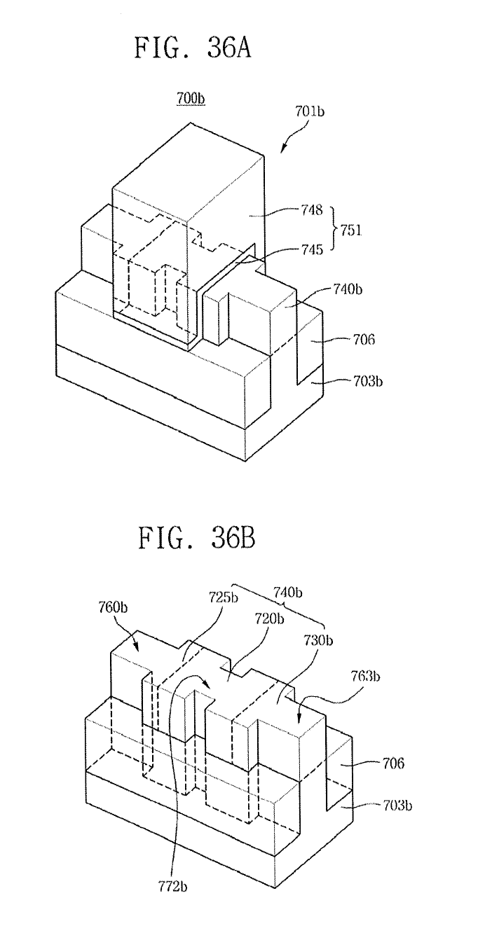

FIG. 36A illustrates a perspective view showing a semiconductor device in accordance with still another embodiment, and FIG. 36B illustrates a perspective view for describing some elements of a semiconductor device in accordance with still another embodiment.

Referring to FIGS. 36A and 36B, a semiconductor device 700b in accordance with still another embodiment may include a finFET 701b. The semiconductor device 700b may include an active region 740b on a substrate 703b, a gate structure 751 on the active region 740b, and a first source/drain region 760b and a second source/drain region 763b in the active region 740b at sides of the gate structure 751. The substrate 703b may be a semiconductor substrate formed of a material such as silicon. The active region 740b may have a shape of a fin protruding from the substrate 703b. An isolation region 706 may be on a part of a side surface of the active region 740b. The isolation region 706 may be formed using a shallow trench isolation process, and formed of an insulating material.

The gate structure 751 may cross the active region 740b, and may surround an upper surface of the active region 740b, and two opposite upper side surfaces of the active region 740b. Lower side surfaces of the active region 740b (under the gate structure 751) may be covered by the isolation region 706.

The gate structure 751, like the gate structure 451 described in FIG. 29A, may include a gate dielectric 745 and a gate electrode 748 on the gate dielectric 745.

The active region 740b may include a first part 720b, and a second part 725b and a third part 730b facing each other with the first part 720b interposed therebetween. The first part 720b of the active region 740b may be a portion overlapped by the gate structure 751. Accordingly, the gate structure 751 may surround an upper surface of the first part 720b of the active region 740b, and two opposite side surfaces of the first part 720b of the active region 740b. A plan view of the active region 740b may be the same as that of the active region 340 described in FIGS. 27A and 27B and FIGS. 28A and 28B. For example, in a plan view, the first part 720b of the active region 740b, like the first part 320 of the active region 340 described in FIGS. 27A and 27B and FIGS. 28A and 28B, may include portions having different widths. The first source/drain region 760b may be in the second part 725b of the active region 740b, and the second source/drain region 763b may be in the third part 730b of the active region 740b. A channel region 772b of the finFET 701b may be in the first part 720b of the active region 740b between the first source/drain region 760b and the second source/drain region 763b.

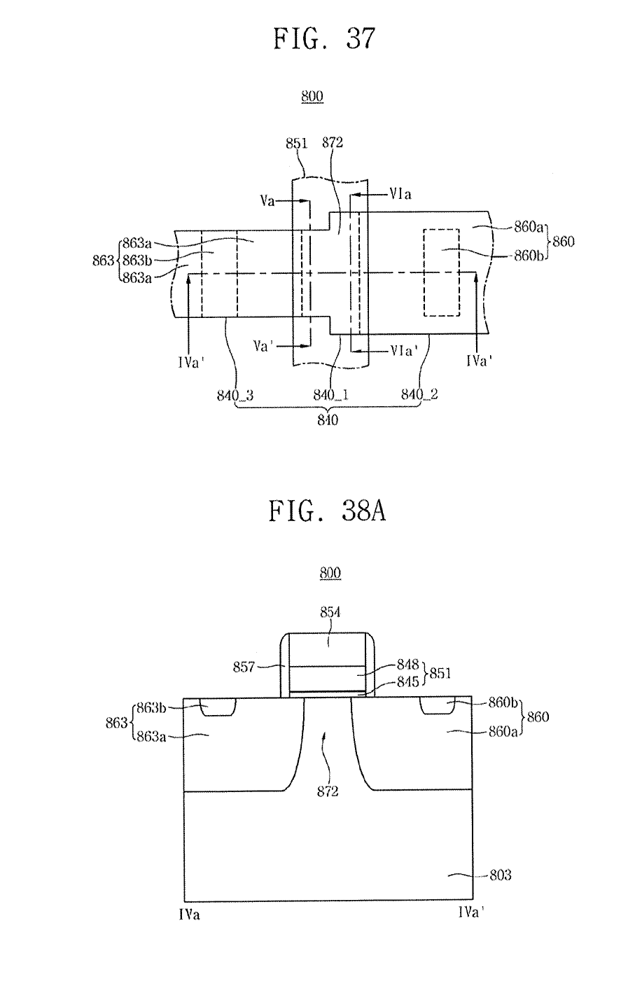

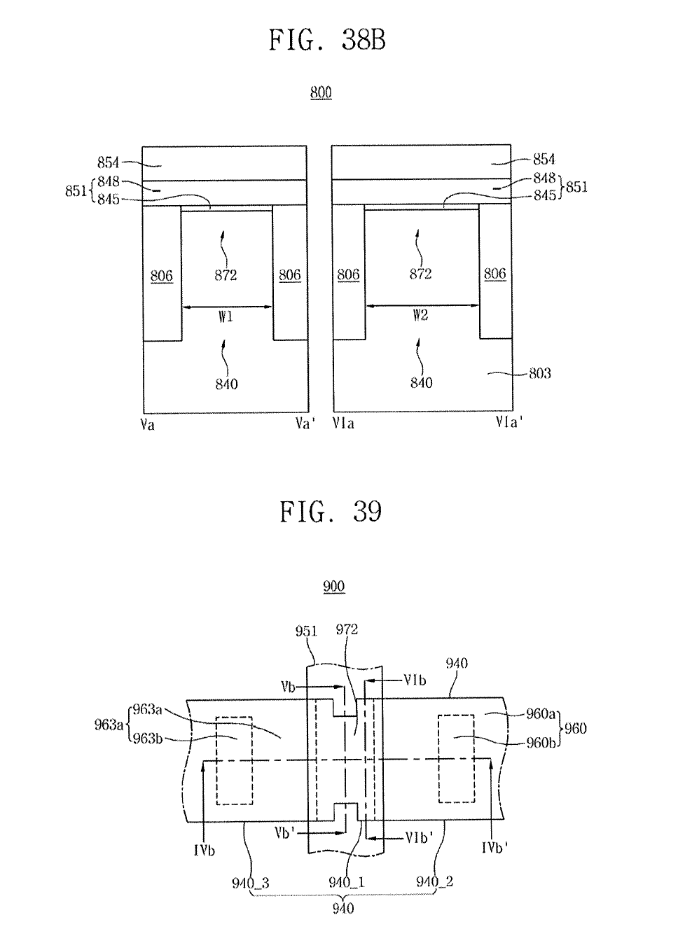

FIG. 37 illustrates a plan view showing a semiconductor device in accordance with still another embodiment, and FIGS. 38A and 38B illustrate cross-sectional views showing a semiconductor device in accordance with still another embodiment. In FIGS. 38A and 38B, FIG. 38A illustrates a cross-sectional view showing an area taken along line IVa-IVa′ of FIG. 37, and FIG. 38A illustrates a cross-sectional view showing an area taken along line Va-Va′ of FIG. 37 and an area taken along line VIa-VIa′ of FIG. 37.

Referring to FIGS. 37, 38A, and 38B, a semiconductor device 800 in accordance with still another embodiment may include an active region 840 on a semiconductor substrate 803, a gate structure 851 on the active region 840, and a drain region 860 and a source region 863 formed in the active region 840 disposed at both sides of the gate structure 851. The active region 840 may be defined as an isolation region 806 formed in the semiconductor substrate 803.

The gate structure 851, like the gate structure 51a described in FIGS. 1A and 1B and FIGS. 2A and 2B, may include a gate electrode 848 on the active region 840, and a gate dielectric 845 between the gate electrode 848 and the active region 840. The gate electrode 848 may cross the active region 840.

A gate capping pattern 854 may be disposed on the gate electrode 848. The gate capping pattern 854 may be formed of an insulating material, such as silicon oxide or silicon nitride. A gate spacer 857 may be disposed on side surfaces of the gate structure 851 and the gate capping pattern 854. The gate spacer 857 may be formed of an insulating material, such as silicon oxide, silicon nitride, or a high-k dielectric material.

The active region 840 may include a first part 840_1 overlapped by the gate structure 851, and a second part 840_2 and a third part 840_3 facing each other with the first part 840_1 interposed therebetween. The first part 840_1 of the active region 840 may be overlapped by the gate electrode 848 of the gate structure 851.

A drain region 860 and a source region 863 may be formed in the active region 840. A channel region 872 may be formed in the active region 840 between the source region 863 and the drain region 860. The channel region 872 may be formed in the first part 840_1 of the active region 840 and may be overlapped by the gate structure 851.

The channel region 872, the source region 863, the drain region 860, and the gate structure 851 may configure a transistor. The transistor may be a MOSFET. For example, the transistor may be an N-MOSFET or a P-MOSFET. When the transistor is the N-MOSFET, the source region 863 and the drain region 860 may have N-type conductivity, and the active region disposed between the source region 863 and the drain region 860 may have P-type conductivity. When the transistor is a PMOSFET, the source region 863 and the drain region 860 may have P-type conductivity, and the active region disposed between the source region 863 and the drain region 860 may have N-type conductivity.

The drain region 860 may include a first drain region 860a and a second drain region 860b. The first drain region 860a may be formed in the second part 840_2 of the active region 840, and may have a portion extending into the first part 840_1 of the active region 840 under the gate structure 851. The second drain region 860b may be formed in the first drain region 860a disposed in the second part 840_2 of the active region 840 and may have side and bottom surfaces surrounded by the first drain region 860a. The second drain region 860b may be spaced apart from the isolation region 806 and a side surface of the active region 840. In addition, the second drain region 860b may be formed shallower than the first drain region 860a.

The second drain region 860b may be a higher concentration impurity region than the first drain region 860a. For example, in an N-MOSFET, the first drain region 860a may be a low concentration N-type area, and the second drain region 860b may be a high concentration N-type area. In a P-MOSFET, the first drain region 860a may be a low concentration P-type area, and the second drain region 860b may be a high concentration P-type area.

The second drain region 860b having high concentration may be shallower than the first drain region 860a having low concentration and surrounded by the first drain region 860a, break down voltage characteristics of the transistor may be improved, and thereby reliability of the semiconductor device may be improved.

The source region 863 may include a first source region 863a and a second source region 863b. The first source region 863a may be formed in the third part 840_3 of the active region 840, and may have a portion extending into the first part 840_1 of the active region 840 under the gate structure 851. The second source region 863b may be formed in the first source region 863a disposed in the third part 840_3 of the active region 840. In addition, the second source region 863b, in a plan view, may cross the first source region 863a. The second source region 863b, in a plan view, may cross the third part 840_3 of the active region 840. The second source region 863b may be formed in the first source region 863a, and may have side and bottom surfaces surrounded by the first source region 863a.

The second source region 863b may be a higher concentration impurity region than the first source region 863a. For example, in an N-MOSFET, the first source region 863a may be a low concentration N-type area, and the second source region 863b may be a high concentration N-type area. In a P-MOSFET, the first source region 863a may be a low concentration P-type area, and the second source region 863b may be a high concentration P-type area. The second source region 863b may cross the third part 840_3 of the active region 840, and On-current of the transistor may increase.

The first part 840_1 of the active region 840, like the first part 20 of the active region 40 described in FIGS. 1A and 1B and FIGS. 2A and 2B, may include a portion having a first width W1, and a portion having a second width W2 that is greater than the first width W1.

In an implementation, “width of an active region” may be defined as a distance between side surfaces of the active region that are overlapped by the gate structure. Accordingly, each of the first and second widths W1 and W2 may be defined as a distance between side surfaces of the active region 840 that are overlapped by the gate structure 851.

Like the first part 20 of the active region 40 described in FIGS. 1A and 1B and FIGS. 2A and 2B, the portion having the second width W2 greater than the first width W1 in the first part 8401 of the active region 840 may be in contact with the second part 840_2 of the active region 840, and the portion having the first width W1 smaller than the second width W2 in the first part 840_1 of the active region 840 may be in contact with the third part 840_3 of the active region 840. Accordingly, since a plan view of the first part 8401 of the active region 840 is substantially the same as a plan view of the first part 20 of the active region 40 described in FIGS. 1A and 1B and FIGS. 2A and 2B, a detailed description thereof may be omitted.

Like the channel region of the active region 40 described in FIGS. 1A and 1B and FIGS. 2A and 2B, the channel region 872 may include a first channel region, and a second channel region having a second channel width W2 greater than a first channel width W1 of the first channel region, and the second channel region may be closer to the drain region 860 than the first channel region. A portion of the channel region 872 of the transistor (which is in contact with the drain region 860) may have the second channel width W2 greater than the first channel width W1 of a portion of the channel region 872 of the transistor which is in contact with the source region 863, and a corner effect of the transistor may be improved. For example, a hump effect of the transistor may be improved. By improving the corner effect of the transistor, reliability of a semiconductor device may increase.

Hereinafter, still other embodiments of a semiconductor device that helps improve the hump effect of a transistor will be described.

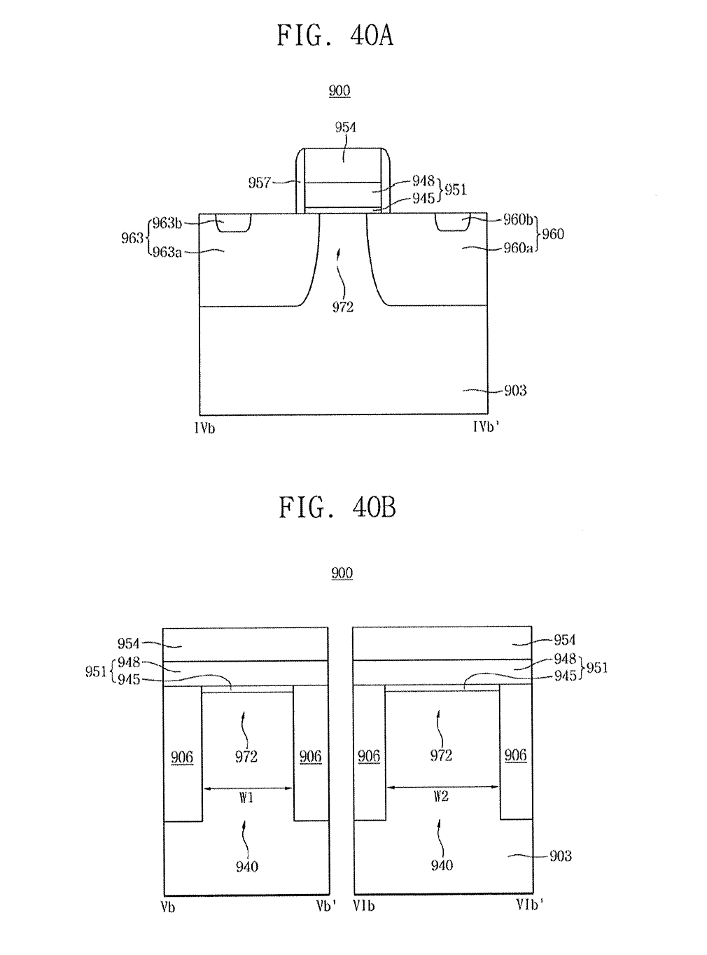

FIG. 39 illustrates a plan view showing a semiconductor device in accordance with still another embodiment, and FIGS. 40A and 40B illustrate cross-sectional views showing a semiconductor device in accordance with still another embodiment. In FIGS. 40A and 4013, FIG. 40A illustrates a cross-sectional view showing an area taken along line IVb-IVb′ of FIG. 39, and FIG. 40B illustrates a cross-sectional view showing an area taken along line Vb-Vb′ of FIG. 39 and an area taken along line VIb-VIb′ of FIG. 39.

Referring to FIGS. 39, 40A and 40B, a semiconductor device 900 in accordance with still another embodiment may include an active region 940 on a semiconductor substrate 903, a gate structure 951 on the active region 940, and a first source/drain region 960 and a second source/drain region 963 formed in the active region 940 at sides of the gate structure 951. The active region 940 may be defined by an isolation region 906 formed in the semiconductor substrate 903.

The gate structure 951, like the gate structure 151a described in FIGS. 13A, 13B and FIGS. 14A and 14B, may include a gate electrode 948 on the active region 940, and a gate dielectric 945 between the gate electrode 948 and the active region 940. The gate electrode 948 may cross the active region 940.

An insulative gate capping pattern 954 may be formed on the gate electrode 948. An insulative gate spacer 957 may be formed on side surfaces of the gate structure 951 and the gate capping pattern 954.

The active region 940 may include a first part 940_1 overlapped by the gate structure 951, and a second part 940_2 and a third part 940_3 facing each other with the first part 940_1 interposed therebetween. The first part 940_1 of the active region 940 may be overlapped by the gate electrode 948 of the gate structure 951.

The first part 940_1 of the active region 940, like the first part 120 of the active region 140 described in FIGS. 13A and 13B and FIGS. 14A and 14B, may have a smaller width at a portion spaced apart from the second and third parts 940_2 and 940_3 than at a portion adjacent to or in contact with the second and third parts 940_2 and 940_3. Accordingly, since a plan view of the first part 940_1 of the active region 940 may be substantially the same as a plan view of the first part 120 of the active region 140 described in FIGS. 13A and 13B and FIGS. 14A and 14B, a detailed description thereof may be omitted.

A first source/drain region 960 and a second source/drain region 963 may be formed in the active region 940. A channel region 972 may be formed in the active region 940 between the first source/drain region 960 and the second source/drain region 963.

The channel region 972, the first and second source/drain regions 960 and 963, and the gate structure 951 may configure a transistor. In the transistor, one of the first and second source/drain regions 960 and 963 may be a source, and the other of the first and second source/drain regions 960 and 963 may be a drain.

Each of the first and second source/drain regions 960 and 963, like the drain region 860 described in FIG. 37 and FIGS. 38A and 38B, may include low concentration source/drain regions 960a and 963a, and high concentration source/drain regions 960b and 963b formed shallower than the low concentration source/drain regions 960a and 963a and having side and bottom surfaces surrounded by the low concentration source/drain regions 960a and 963a. The high concentration source/drain regions 960b and 963b may have a higher impurity concentration than the low concentration source/drain regions 960a and 963a.

By forming the high concentration source/drain regions 960b and 963b to be shallower than the low concentration source/drain regions 960a and 963a, and to be surrounded by the low concentration source/drain regions 960a and 963a, break down voltage characteristics of the transistor may be improved, and thereby, reliability of the semiconductor device will increase.

In addition, the channel region 972 may be formed in the first part 940_1 of the active region 940 (which partially has a small width), and hump characteristics of the transistor may be improved.

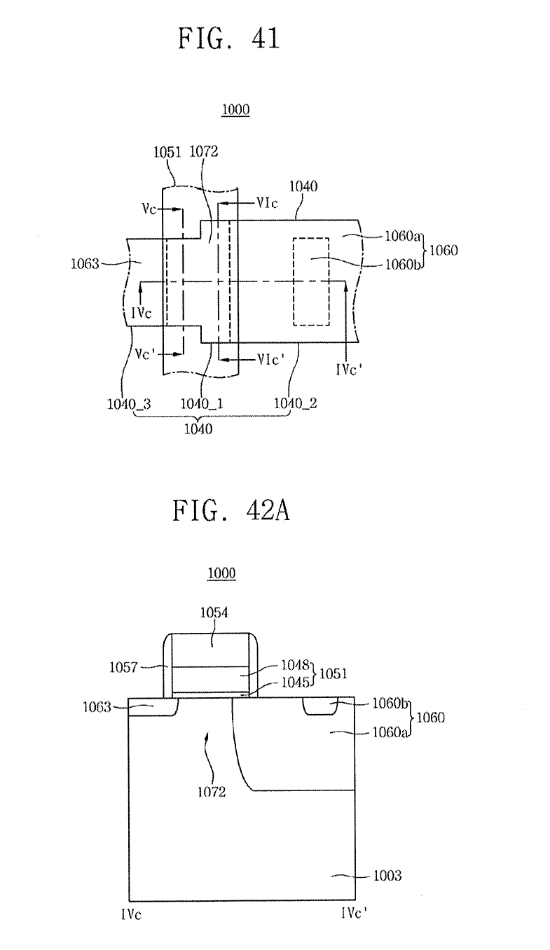

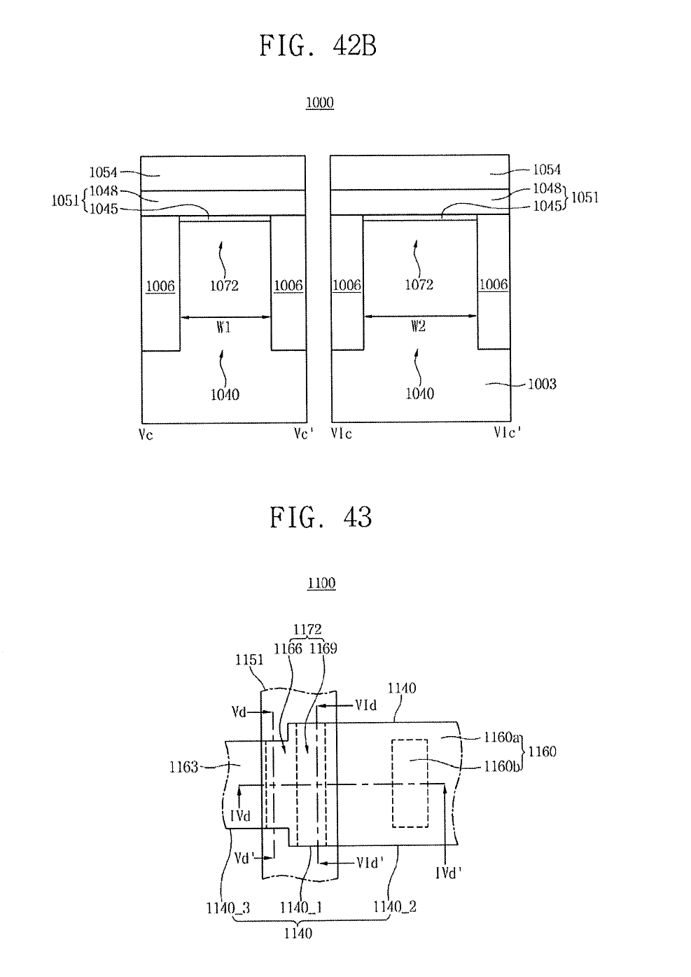

FIG. 41 illustrates a plan view showing a semiconductor device in accordance with still another embodiment, and FIGS. 42A and 4213 illustrate cross-sectional views showing a semiconductor device in accordance with still another embodiment. In FIGS. 42A and 42B, FIG. 42A illustrates a cross-sectional view showing an area taken along line IVc-IVc′ of FIG. 41, and FIG. 42B illustrates a cross-sectional view showing an area taken along line Vc-Vc′ of FIG. 41 and an area taken along line VIc-VIc′ of FIG. 41.

Referring to FIG. 41, and FIGS. 42A and 42B, a semiconductor device 1000 in accordance with still another embodiment may include an active region 1040 on a semiconductor substrate 1003, a gate structure 1051 on the active region 1040, and a drain region 1060 and a source region 1063 formed in the active region 1040 at sides of the gate structure 1051. The active region 1040 may be defined by an isolation region 1006 formed in the semiconductor substrate 1003. A channel region 1072 may be formed in the active region 1040 disposed between the source region 1063 and the drain region 1060. The source region 1063, the drain region 1060, the channel region 1072, and the gate structure 1051 may configure a transistor.

The gate structure 1051 may include a gate electrode 1048 crossing the active region 1040, and a gate dielectric 1045 disposed between the gate electrode 1048 and the active region 1040. An insulative gate capping pattern 1054 may be formed in the gate electrode 1048. An insulative gate spacer 1057 may be formed on side surfaces of the gate structure 1051 and the gate capping pattern 1054.

The active region 1040 may include a first part 1040_1 overlapped by the gate structure 1051, and a second part 10402 and a third part 1040_3 facing each other with the first part 10401 interposed therebetween.

The source region 1063 may be formed in a shallower junction structure than the drain region 1060. For example, the source region 1063 may form a junction at a shallower depth than the drain region 1060. The source region 1063 may be formed in the third part 1040_3 of the active region 1040.

The drain region 1060 may be formed in the second part 1040_2 of the active region 1040. The drain region 1060 may have the same structure as the drain region 860 described in FIGS. 37, 38A, and 38B. For example, the drain region 1060 may include a first drain region 1060a, and a second drain region 1060b formed shallower than the first drain region 1060a and having side and bottom surfaces surrounded by the first drain region 1060a. The second drain region 1060b may have a higher impurity concentration than the first drain region 1060a. In addition, the second drain region 1060b may not be overlapped by the gate structure 1051.

The area occupied by the source region 1063 may be minimized, and a chip size of a semiconductor device may be reduced. Accordingly, a size of semiconductor components may be reduced.

The second drain region 1060b may be formed shallower than the first drain region 1060a, and may be surrounded by the first drain region 1060a, break down voltage characteristics of the transistor may be improved, and thereby reliability of a semiconductor device may be improved.

A plan view of the first part 10401 of the active region 1040 overlapped by the gate structure 1051 may be substantially the same as the plan view of the first part 20 of the active region 40 described in FIGS. 1A and 1B and FIGS. 2A and 2B. The first part 1040_1 of the active region 1040, like the first part 20 of the active region 40 described in FIGS. 1A and 1B and FIGS. 2A and 2B, may include a portion having a first width W1, and a portion having a second width W2 greater than the first width W1.

In the first part 1040_1 of the active region 1040, the portion having the second width W2 may be in contact with the drain region 1060, and the portion having the first width W1 may be in contact with the source region 1063.

The channel region 1072 formed in the first part 1040_1 of the active region 1040 between the source region 1063 and the drain region 1060 may have the same plan view as the channel region 72a described in FIGS. 1A and 1B and FIGS. 2A and 2B, and the channel region 1072 may improve hump characteristics of the transistor.

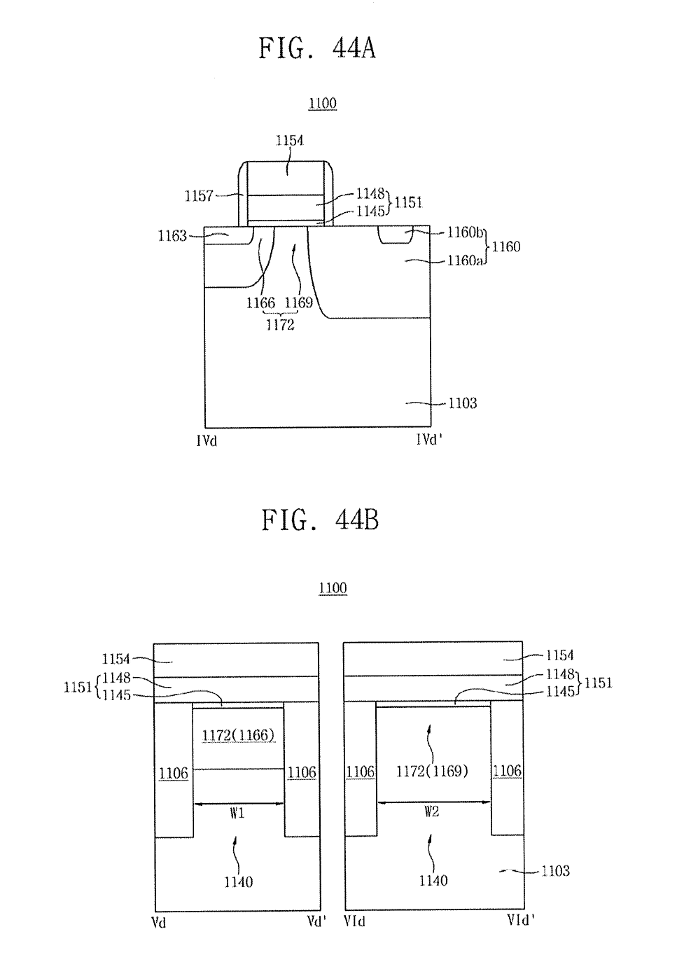

FIG. 43 illustrates a plan view showing a semiconductor device in accordance with still another embodiment, and FIGS. 44A and 44B illustrate cross-sectional views showing a semiconductor device in accordance with still another embodiment. In FIGS. 44A and 44B. FIG. 44A illustrates a cross-sectional view showing an area taken along line IVd-IVd′ of FIG. 43, and FIG. 44B illustrates a cross-sectional view showing an area taken along line Vd-Vd′ of FIG. 43 and an area taken along line VId-VId′ of FIG. 43.

Referring to FIGS. 43, 44A, and 44B, a semiconductor device 1100 in accordance with still another embodiment may include an active region 1140 on a semiconductor substrate 1103, a gate structure 1151 on the active region 1140, and a drain region 1160 and a source region 1163 formed in the active region 1140 at sides of the gate structure 1151. The active region 1140 may be defined by an isolation region 1106 formed in the semiconductor substrate 1103. A channel region 1172 may be formed in the active region 1140 between the source region 1163 and the drain region 1160. The source region 1163, the drain region 1160, the channel region 1172, and the gate structure 1151 may configure a transistor.

The gate structure 1151 may include a gate electrode 1148 crossing the active region 1140, and a gate dielectric 1145 disposed between the gate electrode 1148 and the active region 1140. An insulative gate capping pattern 1154 may be formed on the gate electrode 1148. An insulative gate spacer 1157 may be formed on side surfaces of the gate structure 1151 and the gate capping pattern 1154.

The active region 1140 may include a first part 1140_1 overlapped by the gate structure 1151, and a second part 1140_2 and a third part 1140_3 facing each other with the first part 1140_1 interposed therebetween.

The source region 1163 may be formed in the third part 1140_3 of the active region 1140. The source region 1163, like the source region 1063 described in FIGS. 41, 42A, and 42B, may be formed to have a shallower junction structure than the drain region 1160.

The drain region 1160 may be formed in the second part 1140_2 of the active region 1140. The drain region 1160, like the drain region 1060 described in FIGS. 41, 42A, and 42B, may include a first drain region 1160a, and a second drain region 1160b formed shallower than the first drain region 1160a and having side and bottom surfaces surrounded by the first drain region 1160a. The second drain region 1160b may have a higher impurity concentration than the first drain region 1160a. In addition, the second drain region 1160b may not be overlapped by the gate structure 1151.

A channel impurity region 1166 may surround bottom and side surfaces of the source region 1163. The channel impurity region 1166 may include a portion overlapped by the gate structure 1151. The channel impurity region 1166 may be spaced apart from the drain region 1160. The channel impurity region 1166 and a portion 1169 between the channel impurity region 1166 and the drain region 1160 may be defined as a channel region 1172 of the transistor.

The channel impurity region 166 may have the same conductivity type as the active region 1140, and a higher impurity concentration than the active region 1140. Accordingly, the channel impurity region 1166 may help increase an operation speed of the transistor. The transistor including the channel impurity region 1166 may be used to function to switch a high power device.

A portion of the channel region 1172 in contact with the drain region 1160 may have a greater channel width than a portion of the channel region 1172 in contact with the source region 1163. Accordingly, hump characteristics of the transistor may be improved.

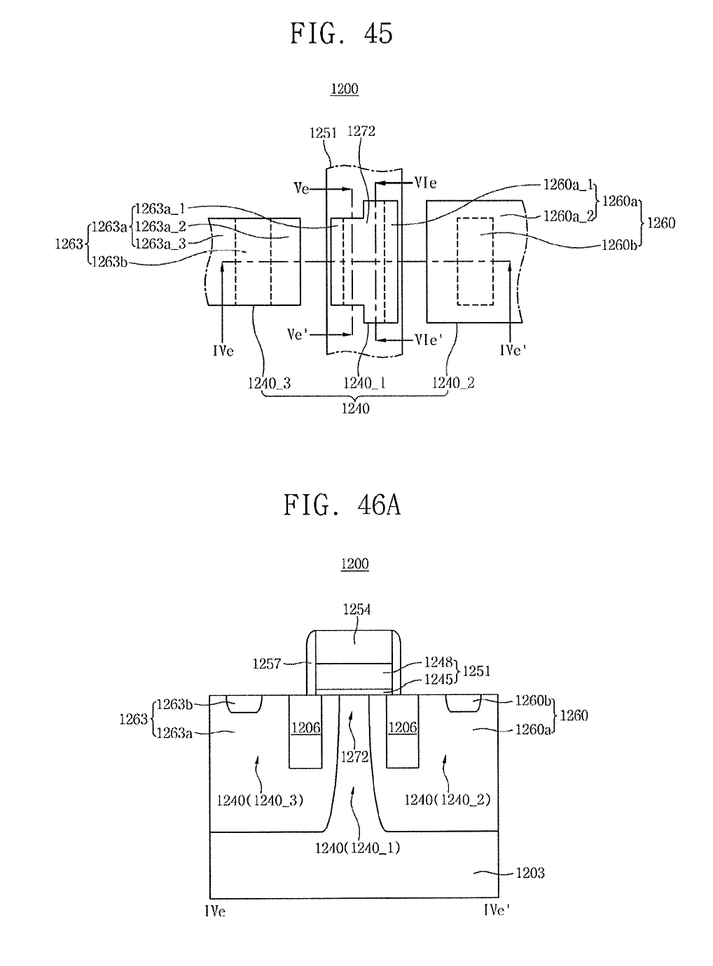

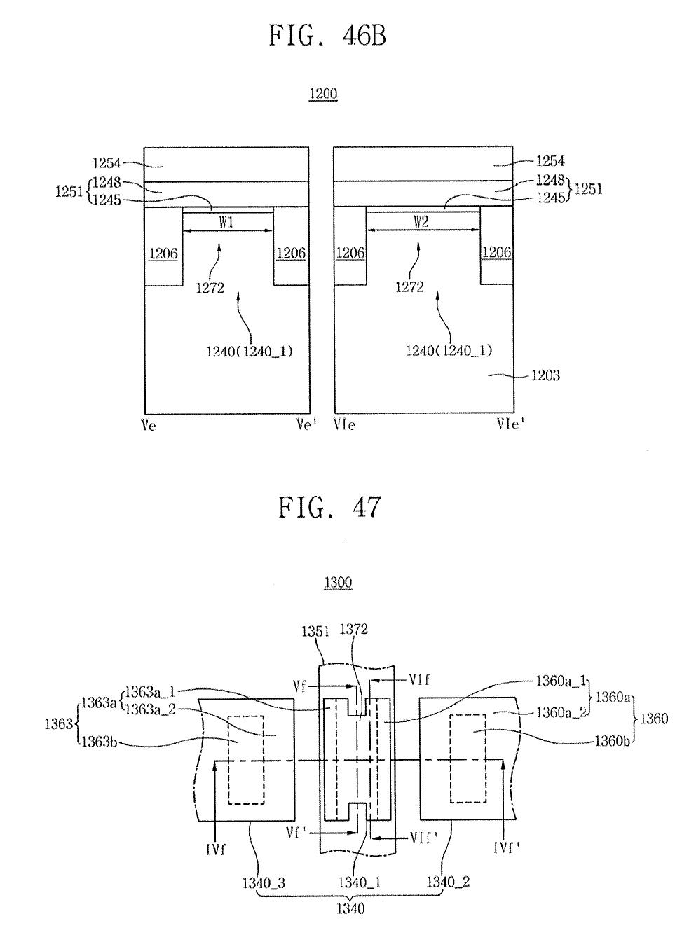

FIG. 45 illustrates a plan view showing a semiconductor device in accordance with still another embodiment, and FIGS. 46A and 46B illustrate cross-sectional views showing a semiconductor device in accordance with still another embodiment. In FIGS. 46A and 46B, FIG. 46A illustrates a cross-sectional view showing an area taken along line IVe-IVe′ of FIG. 45, and FIG. 46B illustrates a cross-sectional view showing an area taken along line Ve-Ve′ of FIG. 45 and an area taken along line Vie-VIe′ of FIG. 45.

Referring to FIGS. 45, 46A, and 46B, a semiconductor device 1200 in accordance with still another embodiment may include a gate structure 1251 on a substrate 1203, and a drain region 1260 and a source region 1263 formed in an active region 1240 at sides of the gate structure 1251. In addition, the semiconductor device 1200 may include an isolation region 1206 formed in the semiconductor substrate 1203 and defining the active region 1240.

The gate structure 1251 may include a gate electrode 1248 crossing the active region 1240, and a gate dielectric 1245 between the gate electrode 1248 and the active region 1240. An insulative gate capping pattern 1254 may be formed on the gate electrode 1248. An insulative gate spacer 1257 may be formed on side surfaces of the gate structure 1251 and the gate capping pattern 1254.

A channel region 1272 may be formed in the active region 1240 between the source region 1263 and the drain region 1260. The source region 1263, the drain region 1260, the channel region 1272, and the gate structure 1251 may configure a transistor.

In a plan view, the active region 1240 may include first to third parts 1240_1, 1240_2, and 1240_3, which are isolated by the isolation region 1206.

The first part 1240_1 of the active region 1240 may be between the second and the third parts 1240_2 and 1240_3 of the active region 1240. The first part 1240_1 of the active region 1240 may be overlapped by the gate structure 1251.

The drain region 1260 may include a first drain region 1260a, and a second drain region 1260b formed shallower than the first drain region 1260a and having side and bottom surfaces of the first drain region 1260a. The second drain region 1260b may have a higher impurity concentration than the first drain region 1260a. In addition, the second drain region 1260b may not be overlapped by the gate structure 1251, and may be formed at a higher level than a bottom surface of the isolation region 1206. The structure of the drain region 1260 may help improve breakdown voltage characteristics of the transistor.

The first drain region 1260a may surround side and bottom surfaces of the isolation region 1206 between the first part 1240_1 of the active region 1240 and the second part 1240_2 of the active region 1240. The first drain region 1260a may be formed in the second part 1240_2 of the active region 1240, and extend to a portion of the first part 1240_1 of the active region 1240.

A portion 1260a_1 of the first drain region 1260a formed in a portion of the first part 1240_1 of the active region 1240 may be overlapped by the gate structure 1251. A portion 1260a_2 of the first drain region 1260a formed in a portion of the second part 1240_2 of the active region 1240 may surround bottom and side surfaces of the second drain region 1260b.

The source region 1263 may include a first source region 1263a, and a second source region 1263b, which is formed shallower than the first source region 1263a and is not overlapped by the gate structure 1251. The second source region 1263b may have a high impurity concentration than the first source region 1263a. In addition, the second source region 1263b may be formed to cross the third part 1240_3 of the active region 1240, in order to help improve On-current characteristics of the transistor.

The first source region 1263a may surround side and bottom surfaces of the isolation region 1206 disposed between the first part 1240_1 of the active region 1240 and the third part 1240_3 of the active region 1240.

The first source region 1263a may be formed in the third part 1240_3 of the active region 1240, and may extend to a portion of the first part 1240_1 of the active region 1240. A portion 1263a_1 of the first source region 1263a formed in a portion of the first part 1240_1 of the active region 1240 may be overlapped by the gate structure 1251. In a plan view, the second source region 1263b may be between portions 1263a_2 and 1263a_3 of the first source region 1263a.

The drain region 1260 may be formed at an end of the first part 1240_1 of the active region 1240 adjacent to the second part 1240_2 of the active region 1240, and the source region 1263 may be formed at an end of the first part 1240_1 of the active region 1240 adjacent to the third part 1240_3 of the active region 1240. In addition, the channel region 1272 may be formed in the first part 1240_1 of the active region 1240 between the source region 1263 and the drain region 1260.

The channel region 1272 may have a first width W1 at a portion adjacent to the source region 1263, and a second width W2 greater than the first width W1 at a portion adjacent to the drain region 1260. The structure of the channel region 1272 may help improve hump characteristics of the transistor. In addition, the transistor may be used in a power device.

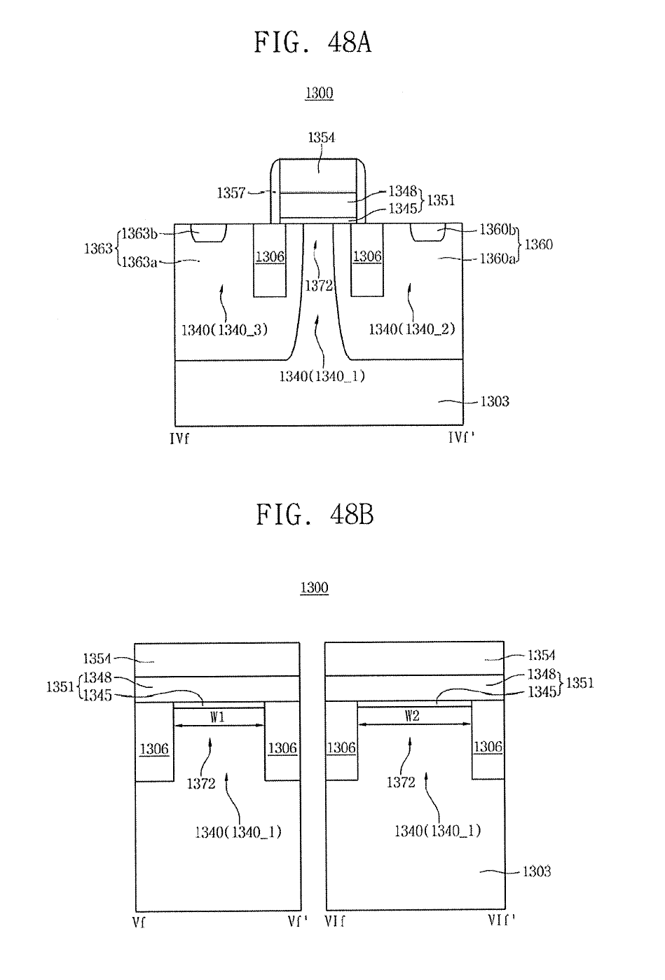

FIG. 47 illustrates a plan view showing a semiconductor device in accordance with still another embodiment, and FIGS. 48A and 48B illustrate cross-sectional views showing a semiconductor device in accordance with still another embodiment. In FIGS. 48A and 48B, FIG. 48A illustrates a cross-sectional view showing an area taken along line IVf-IVf′ of FIG. 47, and FIG. 48B illustrates a cross-sectional view showing an area taken along line Vf-Vf′ of FIG. 47 and an area taken along line VIf-VIf′ of FIG. 47.

Referring to FIGS. 47, 48A, and 48B, a semiconductor device 1300 in accordance with still another embodiment may include a gate structure 1351 on a semiconductor substrate 1303, and a first source/drain region 1360 and a second source/drain region 1363 formed in an active region 1340 at sides of the gate structure 1351. In addition, the semiconductor device 1300 may include an isolation region 1306 formed in the semiconductor substrate 1303 and defining the active region 1340.

The gate structure 1351 may include a gate electrode 1348 crossing the active region 1340, and a gate dielectric 1345 between the gate electrode 1348 and the active region 1340. An insulative gate capping pattern 1354 may be formed on the gate electrode 1348. An insulative gate spacer 1357 may be formed on side surfaces of the gate structure 1351 and the gate capping pattern 1354.

A channel region 1372 may be formed in the active region 1340 between the first source/drain region 1360 and the second source/drain region 1363. The first source/drain region 1360, the second source/drain region 1363, the channel region 1372, and the gate structure 1351 may configure a transistor. One of the first and second source/drain regions 1360 and 1363 may be a source of the transistor, and the other may be a drain of the transistor.

In a plan view, the active region 1340 may include first to third parts 1340_1, 1340_2, and 1340_3 isolated by the isolation region 1306.

The first part 1340_1 of the active region 1340 may be between the second and third parts 1340_2 and 1340_3 of the active region 1340. The first part 1340_1 of the active region 1340 may be overlapped by the gate structure 1351.

The first source/drain region 1360 may include a first low concentration source/drain region 1360a, and a first high concentration source/drain region 1360b formed shallower than the first low concentration source/drain region 1360a and having side and bottom surfaces surrounded by the first low concentration source/drain region 1360a. The first high concentration source/drain region 1360b may have a higher impurity concentration than the first low concentration source/drain region 1360a. The first high concentration source/drain region 1360b may be formed in the second part 1340_2 of the active region 1340, and may not be overlapped by the gate structure 1351.

The first low concentration source/drain region 1360a, like the first drain region 1260a described in FIGS. 45, 46A, and 46B, may surround side and bottom surfaces of the isolation region 1306 located between the first part 1340_1 of the active region 1340 and the second part 1340_2 of the active region 1340.

A portion 1360a_1 of the first low concentration source/drain region 1360a formed in a portion of the first part 1340_1 of the active region 1340, may be overlapped by the gate structure 1351. In addition, a portion 1360a_2 of the first low concentration source/drain region 1360a formed in the second part 1340_2 of the active region 1340 may surround bottom and side surfaces of the first high concentration source/drain region 1360b.

The second source/drain region 1363 and the first source/drain region 1360 may have mirror symmetry. For example, the second source/drain region 1363 may include a second low concentration source/drain region 1363a, and a second high concentration source/drain region 1363b formed shallower than the second low concentration source/drain region 1363a, and having side and bottom surfaces surrounded by the second low concentration source/drain region 1363a. The second high concentration source/drain region 1363b may be formed in the third part 1340_3 of the active region 1340, and may not be overlapped by the gate structure 1351.

The second low concentration source/drain region 1363a may surround side and bottom surfaces of the isolation region 1306 between the first part 1340_1 of the active region 1340 and the third part 1340_3 of the active region 1340.

A portion 1363a_1 of the second low concentration source/drain region 1363a formed in a portion of the first part 1340_1 of the active region 1340 may be overlapped by the gate structure 1351. A portion 1363a_2 of the second low concentration source/drain region 1363a formed in the third part 1340_3 of the active region 1340 may surround bottom and side surfaces of the second high concentration source/drain region 1363b.

In a plan view, the first part 13401 of the active region 1340 may have a portion having a first width W1, and a portion having a second width W2 greater than the first width W1 and formed at sides of the portion having the first width W1.

The channel region 1372 of the active region 1340 may be formed in the portion having the first width W1 and the portion having the second width W2 of the first part 1340_1 of the active region 1340. The structure of the channel region 1372 may help improve hump characteristics of the transistor. In addition, the transistor may be used in a power device.

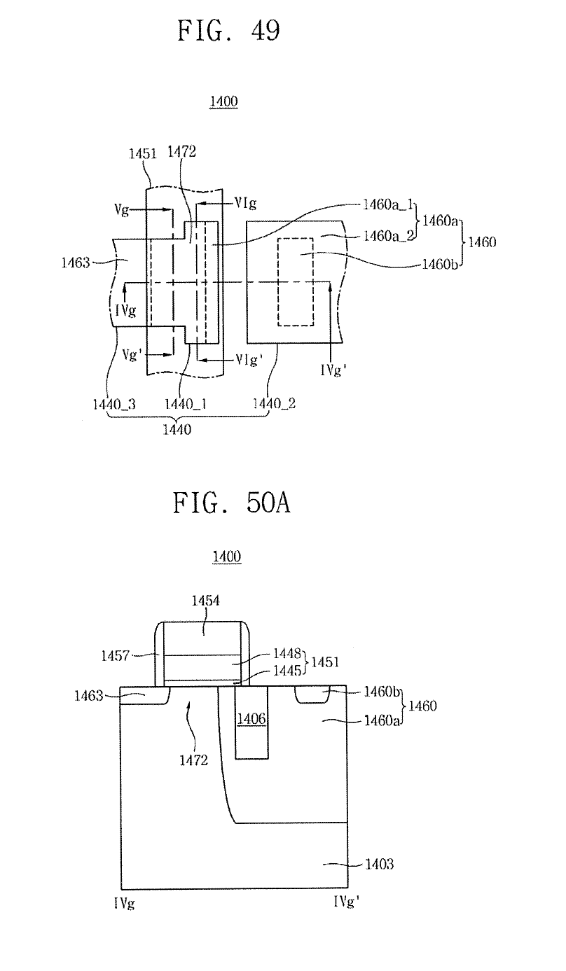

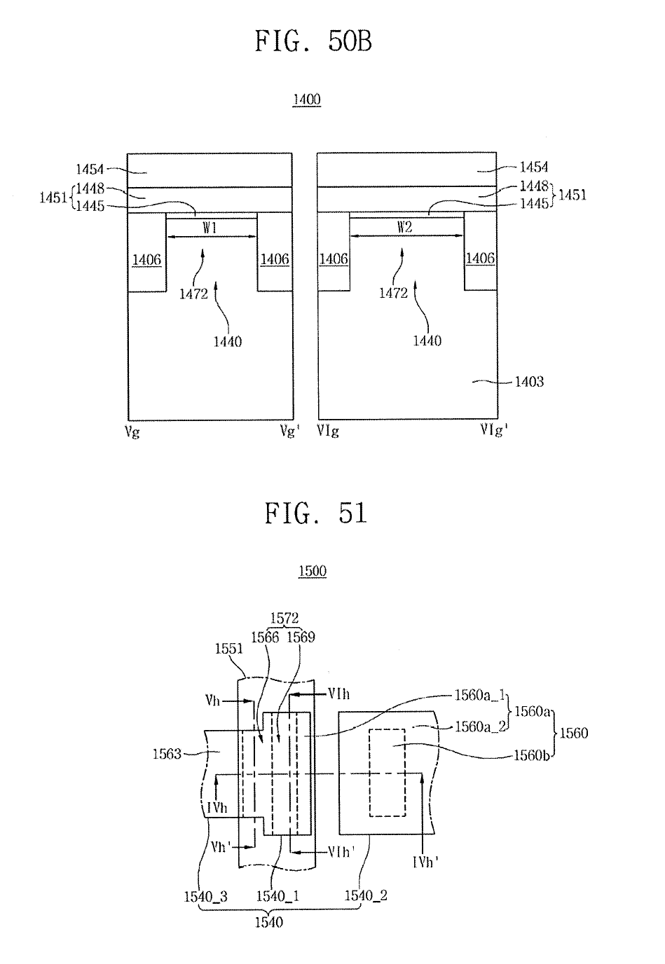

FIG. 49 illustrates a plan view showing a semiconductor device in accordance with still another embodiment, and FIGS. 50A and 508 illustrate cross-sectional views showing a semiconductor device in accordance with still another embodiment. In FIGS. 50A and 508, FIG. 50A illustrates a cross-sectional view showing an area taken along line IVg-IVg′ of FIG. 49, and FIG. 508 illustrates a cross-sectional view showing an area taken along line Vg-Vg′ of FIG. 49 and an area taken along line VIg-VIg′ of FIG. 49.

Referring to FIGS. 49, 50A, 50B, a semiconductor device 1400 in accordance with still another embodiment may include a gate structure 1451 on a semiconductor substrate 1403, and a drain region 1460 and a source region 1463 formed in an active region 1440 at sides of the gate structure 1451. In addition, the semiconductor device 1400 may include an isolation region 1406 formed in the semiconductor substrate 1403 and defining the active region 1440.

The gate structure 1451 may include a gate electrode 1448 crossing the active region 1440, and a gate dielectric 1445 between the gate electrode 1448 and the active region 1440. An insulative gate capping pattern 1454 may be formed on the gate electrode 1448. An insulative gate spacer 1457 may be formed on side surfaces of the gate structure 1451 and the gate capping pattern 1454.

A channel region 1472 may be formed in the active region 1440 between the source region 1463 and the drain region 1460. The source region 1463, the drain region 1460, the channel region 1472, and the gate structure 1451 may configure a transistor.

The active region 1440 may include a first part 1440_1 overlapped by the gate structure 1451, and a second part 1440_2 and a third part 1440_3 facing each other with the first part 1440_1 interposed therebetween.

In a plan view, the first part 1440_1 of the active region 1440 and the second part 1440_2 of the active region 1440 may be isolated by the isolation region 1406.

The source region 1463 may be formed shallower than the drain region 1460. That is, a junction depth of the source region 1463 may be shallower than that of the drain region 1460. The source region 1463 may be formed in the third part 1440_3 of the active region 1440.

The drain region 1460 may include a first drain region 1460a, and a second drain region 1460b formed shallower than the first drain region 1460a and having side and bottom surfaces surrounded by the first drain region 1460a. The second drain region 1460b may have a higher impurity concentration than the first drain region 1460a. The second drain region 1460b may not be overlapped by the gate structure 1451, and may be formed at a higher level than a bottom surface of the isolation region 1406.

The first drain region 1460a may surround side and bottom surfaces of the isolation region 1406 between the first part 1440_1 of the active region 1440 and the second part 1440_2 of the active region 1440. Accordingly, the first drain region 1460a may include a portion 1460a_2 formed in the second part 1440_2 of the active region 1440, and a portion 1460a_1 formed in a portion of the first part 1440_1 of the active region 1440. The structure of the drain region 1460 may help improve breakdown voltage characteristics of the transistor.

The channel region 1472 formed in the first part 1440_1 of the active region 1440 may have a first width W1 at a portion adjacent to the source region 1463, and a second width W2 greater than the first width W1 at a portion adjacent to the drain region 1460. Accordingly, the channel region 1472 may help improve hump characteristics of the transistor.

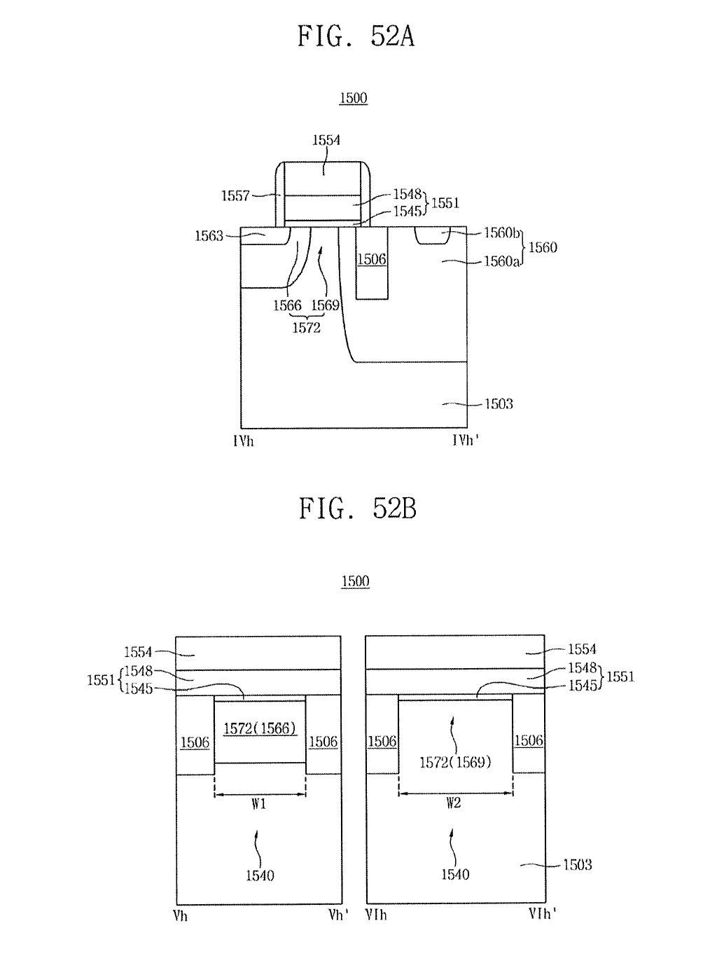

FIG. 51 illustrates a plan view showing a semiconductor device in accordance with still another embodiment, and FIGS. 52A and 52B illustrate cross-sectional views showing a semiconductor device in accordance with still another embodiment. In FIGS. 52A and 52B, FIG. 52A illustrates a cross-sectional view showing an area taken along line IVh-IVh′ of FIG. 51, and FIG. 528 illustrates a cross-sectional view showing an area taken along line Vh-Vh′ of FIG. 51 and an area taken along line VIh-VIh′ of FIG. 51.

Referring to FIGS. 51, 52A, and 52B, a semiconductor device 1500 in accordance with still another embodiment may include a gate structure 1551 on a semiconductor substrate 1503, and a drain region 1560 and a source region 1563 formed in an active region 1540 at sides of the gate structure 1551. In addition, the semiconductor device 1500 may include an isolation region 1506 formed in the semiconductor substrate 1503 and defining the active region 1540. A channel region 1572 may be formed in the active region 1540 disposed between the source region 1563 and the drain region 1560. The source region 1563, the drain region 1560, the channel region 1572, and the gate structure 1551 may configure a transistor.

A plan view of the active region 540 and gate structure 1551 may be substantially the same as a plan view of the active region 1440 and gate structure 1451 described in FIGS. 49, 50A, and 50B.

The gate structure 1551 may include a gate electrode 1548 crossing the active region 1540, and a gate dielectric 1545 between the gate electrode 1548 and the active region 1540. An insulative gate capping pattern 1554 may be formed on the gate electrode 1548. An insulative gate spacer 1557 may be formed on side surfaces of the gate structure 1551 and the gate capping pattern 1554.

The active region 1540 may include a first part 1540_1 overlapped by the gate structure 1551, and a second part 1540_2 and a third part 1540_3 facing each other with the first part 1540_1 interposed therebetween.

In a plan view, the first part 1540_1 of the active region 1540 and the second part 1540_2 of the active region 1540 may be isolated by the isolation region 1506.

Like the source region 1463 and the drain region 1460 described in FIGS. 49, 50A, and 50B, the source region 1563 may be formed shallower than the drain region S560, and the drain region 1560 may include a first drain region 1560a, and a second drain region 1560b formed shallower than the first drain region 1560a and having side and bottom surfaces surrounded by the first drain region 1560a. The second drain region 1560b may have a higher impurity concentration than the first drain region 1560a. The second drain region 1560b may not be overlapped by the gate structure 1551, and may be formed at a higher level than a bottom surface of the isolation region 1506.

The first drain region 1560a may surround side and bottom surfaces of the isolation region 1506 between the first part 1540_1 of the active region 1540 and the second part 1540_2 of the active region 1540. Accordingly, the first drain region 1560a may include a portion 1560a 2 formed in the second part 1540_2 of the active region 1540, and a portion 1560a_1 formed in a portion of the first part 1540_1 of the active region 1540. The structure of the drain region 1560 may help improve breakdown voltage characteristics of the transistor.

A channel impurity area 1566 (surrounding bottom and side surfaces of the source region 1563) may be formed. The channel impurity area 1566 may include a portion overlapped by the gate structure 1551. The channel impurity area 1566 may be spaced apart from the drain region 1560. The channel impurity area 1566, and a portion 1569 of the active region between the channel impurity area 1566 and the drain region 1560 may be defined as a channel region 1572 of the transistor.

The channel impurity area 1566 may have the same conductivity type as the active region 1540, and a higher impurity concentration than the active region 1540. Accordingly, the channel impurity area 1566 may help improve an operation speed of the transistor. The transistor including the channel impurity area 1566 may function as a switch of a high power device.

The channel region 1572 formed in the first part 1540_1 of the active region 1540 may have a first width W1 at a portion adjacent to the source region 1563, and a second width W2 greater than the first width W1 at a portion adjacent to the drain region 1560. Accordingly, the channel region 1572 may help improve hump characteristics of the transistor.

In accordance with embodiments a channel width of a portion connected to a drain region may be increased, and hump characteristics of the transistor may be improved. Likewise, reliability of a semiconductor device including the transistor having improved hump characteristics may be improved.

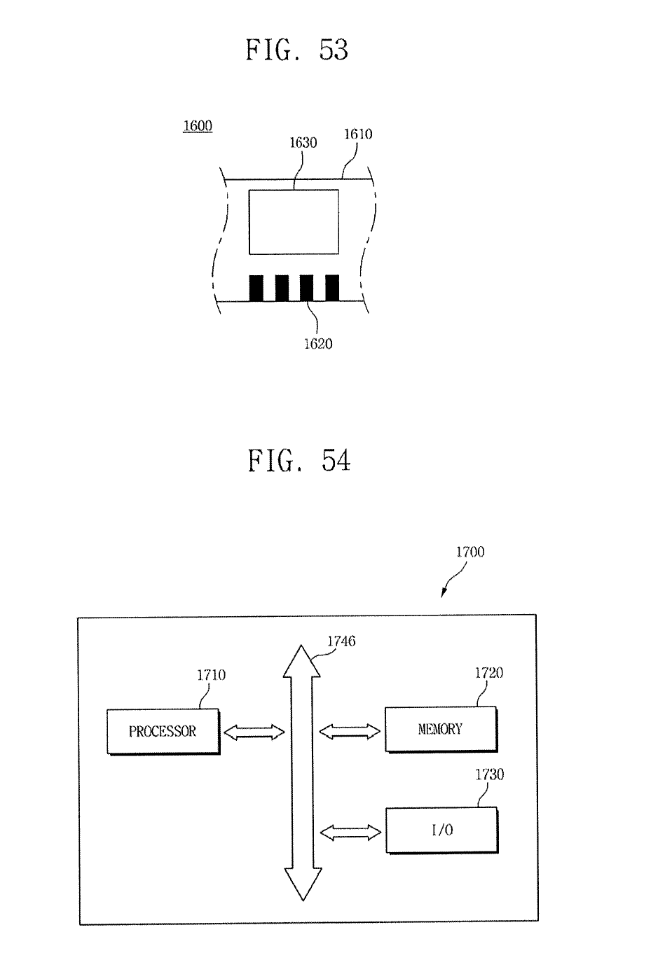

FIG. 53 illustrates a memory card including a semiconductor device in accordance with embodiments.

Referring to FIG. 53, a memory card 1600 may include a card substrate 1610, one or more semiconductor devices 1630 arranged on the card substrate 1610, and contact terminals 1620 formed side by side in an edge of the card substrate 1610 and electrically independently connected to the semiconductor devices 1630.

The semiconductor device 1630 may include a semiconductor device formed in accordance with embodiments. The semiconductor device 1630 may be a component in a form of a memory chip or semiconductor package.

The memory card 1600 may be a memory card available for an electronic apparatus, for example, a digital camera, a tablet PC, a computer, a portable storage apparatus, etc.

The card substrate 1610 may be a printed circuit board (PCB). Both sides of the card substrate 1610 may be available to be used. For example, the semiconductor devices 1630 may be arranged in both front and back surfaces of the card substrate 1610. The semiconductor devices 1630 may be electrically and mechanically connected to the from surface and/or the back surface of the card substrate 1610.

The contact terminals 1620 may be formed of a metal, and may have oxidation resistance. The contact terminals 1620 may be variously set according to types or standards of the memory card 1600. Therefore, the number of the contact terminals 1620 illustrated in FIG. 53 may not have a specific meaning.

FIG. 54 illustrates a block diagram showing an electronic apparatus including a semiconductor device in accordance with embodiments.

Referring to FIG. 54, an electronic apparatus 1700 may be provided. The electronic apparatus 1700 may include a processor 1710, a memory 1720, and an input/output (I/O) 1730. The processor 1710, the memory 1720, and the I/O 1730 may be connected through a bus 1746.

The memory 1720 may receive a control signal such as RAS*, WE*, and CAS* from the processor 1710. The memory 1720 may store codes or data for operating the processor 1710. The memory 1720 may be used to store data accessed through the bus 1746.

The memory 1720 may include a semiconductor device formed in accordance with embodiments. The processor 1710 may include a semiconductor device formed in accordance with embodiments.

The electronic apparatus 1700 may configure a variety of electronic control devices that need the memory 1720. For example, the electronic apparatus 1700 may be used in a computer system, a wireless communication apparatus such as a PDA, a laptop computer, a portable computer, a web tablet, a wireless phone, a mobile phone, a digital music player, an MP3 player, a navigation system, a solid state disk (SS)), a household appliance, or all devices which are capable of transmitting information in a wireless environment.

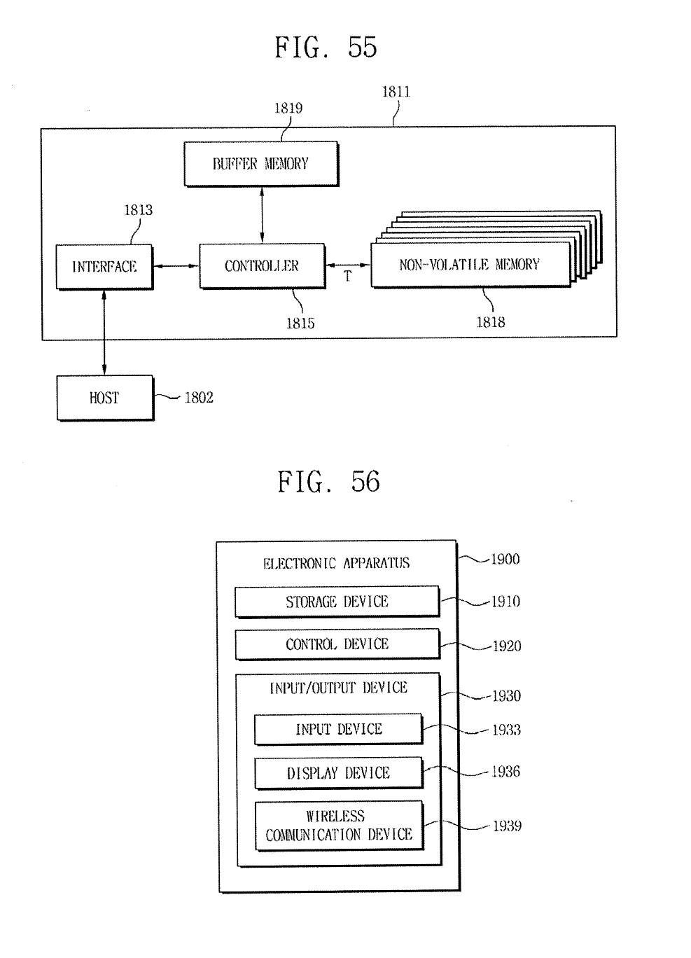

A more specifically implemented and modified example of the electronic apparatus 1700 will be described with reference to FIG. 55.

FIG. 55 illustrates a block diagram showing a data storage apparatus including a semiconductor device formed in accordance with embodiments.

Referring to FIG. 55, the electronic apparatus may be a data storage apparatus such as a solid state disk (SSD) 1811. The SSD 1811 may include an interface 1813, a controller 1815, a non-volatile memory 1818, and a buflfer memory 1819.

The SSD 1811 may be an apparatus that stores information using a semiconductor device. The SSD 1811 is faster, has a lower mechanical delay or failure rate, and generates less heat and noise than a hard disk drive (HDD). Further, the SSD 1811 may be smaller and lighter than the HDD. The SSD 1811 may be widely used in a laptop computer, a net-book, a desktop PC, an MP3 player, or a portable storage device.

The controller 1815 may be formed adjacent to the interface 1813 and electrically connected thereto. The controller 1815 may be a micmrprocessor including a memory controller and a buffer controller. The controller 1815 may include a semiconductor device formed in accordance with embodiments.

The non-volatile memory 1818 may be formed adjacent to the controller 1815 and electrically connected thereto via a connection terminal T. A data storage capacity of the SSD 1811 may correspond to a capacity of the non-volatile memory 1818. The butter memory 1819 may be formed adjacent to the controller 1815 and electrically connected thereto.

The interface 1813 may be connected to a host 1802, and may send and receive electrical signals such as data. For example, the interface 1813 may be a device using a standard such as a Serial Advanced Technology Attachment (SATA), an Integrated Drive Electronics (IDE), a Small Computer System Interface (SCSI), and/or a combination thereof. The non-volatile memory 1818 may be connected to the interface 1813 via the controller 1815.

The non-volatile memory 1818 may function to store data received through the interface 1813. The non-volatile memory 1818 may include a semiconductor device in accordance with embodiments. Even when power supplied to the SSD 1811 is interrupted, the data stored in the non-volatile memory 1818 may be retained.

The buffer memory 1819 may include a volatile memory. The volatile memory may be a Dynamic Random Access Memory (DRAM) and/or a Static Random Access Memory (SRAM). The buffer memory 1819 has a relatively faster operating speed than the non-volatile memory 1818. The buffer memory 1819 may include a semiconductor device formed in accordance with embodiments.

Data processing speed of the interface 1813 may be relatively faster than the operating speed of the non-volatile memory 1818. Here, the buffer memory 1819 may function to temporarily store data. The data received through the interface 1813 may be temporarily stored in the buffer memory 1819 via the controller 1815, and then permanently stored in the non-volatile memory 1818 according to the data write speed of the non-volatile memory 1818. Further, frequently used items of the data stored in the non-volatile memory 1818 may be pre-read and temporarily stored in the buffer memory 1819. That is, the buffer memory 1819 may increase effective operating speed and reduce error rate of the SSD 1811.

FIG. 56 illustrates an electronic apparatus in accordance with an embodiment.

Referring to FIG. 56, an electronic apparatus 1900 may include a storage device 1910, a control device 1920, and an input/output device 1930. The input/output device 1930 may include an input device 1933, a display device 1936, and a wireless communication device 1939.

The storage device 1910 may include one or more different types of storage devices such as a hard disc drive storage device, a non-volatile memory (for example, Flash memory or other EEPROM), and a volatile memory (for example, a battery-based SDRAM or a DRAM). The storage device 1910 may include a semiconductor device in accordance with embodiments.

The control device 1920 may be used to control an operation of the electronic apparatus 1900. For example, the control device 1920 may include a microprocessor, etc. The control device 1920 may include a semiconductor device formed in accordance with embodiments.

The input/output device 1930 may include the input device 1933, a display device 1936, and the wireless communication device 1939.

The input/output device 1930 may be used in supplying data to the electronic apparatus 1900, and supplying data from the electronic apparatus 1900 to external devices. For example, the input/output device 1930 may include a display screen, a button, a port, a touchscreen, a joystick, a click wheel, a scrolling wheel, a touch pad, a keypad, a keyboard, a microphone, or a camera.

The wireless communication device 1939 may include one or more integrated circuits, a power amplifier circuit, a passive RF component, one or more antennas, and a communication circuit such as a radio-frequency (RF) transceiver circuit composed of an RF wireless signal processing circuit. The wireless signals may also be transmitted using a light (for example, an infrared communication). The wireless communication device 1939 may include a semiconductor device in accordance with embodiments.

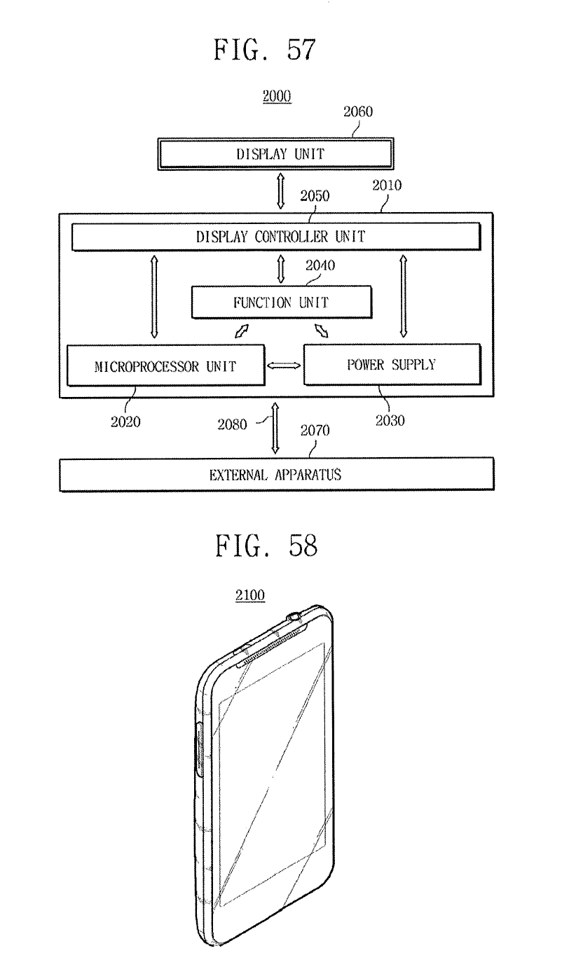

FIG. 57 illustrates a block diagram schematically showing an electronic system including a semiconductor device in accordance with various embodiments.

Referring to FIG. 57, an electronic system 2000 may include a body 2010. The body 2010 may include a microprocessor unit 2020, a power supply unit 2030, a function unit 2040, and/or a display controller unit 2050. The body 2010 may be a system board or motherboard including a printed circuit board (PCB), or the like.

The microprocessor unit 2020 may include a semiconductor device in accordance with embodiments.

The microprocessor unit 2020, the power supply unit 2030, the function unit 2040, and the display controller unit 2050 may be mounted or installed on the body 2010. A display unit 2060 may be arranged on a top surface or outside of the body 2010. For example, the display unit 2060 may be arranged on a surface of the body 2010 and display an image processed by the display controller unit 2050. The power supply unit 2030 may receive a constant voltage from an externmal power source, etc., divide the voltage into various levels, and supply those voltages to the microprocessor unit 2020, the function unit 2040, the display controller unit 2050, etc. The microprocessor unit 2020 may receive a voltage from the power supply unit 2030 to control the function unit 2040 and the display unit 2060.

The function unit 2040 may perform various functions of the electronic system 2000. For example, if the electronic system 2000 is a mobile electronic apparatus such as a mobile phone, the function unit 2040 may have several components which can perform functions of wireless communication such as image output to the display unit 2060 and sound output to a speaker through dialing or communication with an external apparatus 2070, and if a camera is installed, the function unit 2040 may serve as an image processor.

In an implementation, when the electronic system 2000 is connected to a memory card, etc. in order to expend capacity, the function unit 2040 may be a memory card controller. The function unit 2040 may communicate signals with the external apparatus 2070 through a wired or wireless communication unit 2080.

In addition, when the electronic system 2000 needs a universal serial bus (USB), or the like in order to expand functions thereof, the function unit 2040 may serve as an interface controller.

FIG. 58 illustrates a diagram schematically showing an electronic product 2100 including a semiconductor device in accordance with embodiments. The electronic product 2100 may be a mobile wireless phone or a tablet PC. Further, the electronic product 2100 including a semiconductor device in accordance with embodiments may be used in a portable computer such as a notebook, an MPEG-1 Audio Layer 3 (MP3) player, an MP4 player, a navigation apparatus, a solid state disk (SSD), a desktop computer, an automobile, or a home appliance, as well as the mobile wireless phone or the tablet PC.

By way of summation and review, a process of forming a transistor may include forming an isolation region defining an active region in a semiconductor, forming a gate on the active region, and forming a source region and a drain region in the active region at sides of the gate. Phenomena that may occur at an end of the active region under the gate and in contact with the isolation region may be so-called corner effects. A hump effect of a MOSFET may be a representative phenomenon of the corner effects.

A transistor having decreased channel length and channel width may have deteriorated electrical properties due to corner effects, e.g. a hump effect, generated from an edge of an active region in contact with an isolation region.

The embodiments may provide a transistor capable of improving hump characteristics.

The embodiments may provide a semiconductor device including a transistor having improved hump characteristics.

The embodiments may provide a semiconductor device capable of improving reliability of a transistor.

The embodiments may provide an electronic apparatus and electronic system having the semiconductor devices.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
an active region;
a gate electrode on the active region; and
a gate dielectric between the gate electrode and the active region,
wherein:
the active region includes a first part overlapped by the gate electrode, and second and third parts facing each other with the first part therebetween,
the first part of the active region includes a first portion having a first width and a second portion having a second width, the second width being greater than the first width, and
the second portion of the active region is closer to the second part of the active region than to the third part of the active region.

2. The semiconductor device as claimed in claim 1, wherein the second portion of the active region is continuously connected to the second part of the active region.

3. The semiconductor device as claimed in claim 1, wherein the second part of the active region includes a portion having the same width as the second portion of the active region.

4. The semiconductor device as claimed in claim 1, wherein:
the first width of the first portion of the active region and the second width of the second portion of the active region are each defined by distances between two opposite first and second side surfaces of the active region, and
the gate electrode overlies the first and second side surfaces of the active region.

5. The semiconductor device as claimed in claim 1, wherein the first portion of the active region is continuously connected to the third part of the active region.

6. The semiconductor device as claimed in claim 1, wherein the third part of the active region includes a portion having the same width as the first portion of the active region.

7. The semiconductor device as claimed in claim 1, wherein:
the first part of the active region further includes a third portion facing the second portion of the active region, the first portion of the active region being interposed between the second portion and the third portion, and
the third portion of the active region has a third width, the third width being greater than the first width.

8. The semiconductor device as claimed in claim 1, wherein one of the second and third parts of the active region has:
the same width as the second portion of the active region at a portion thereof that is in contact with the first part, and
a smaller width than the second portion of the active region at a portion thereof that is spaced apart from the first part of the active region.

9. The semiconductor device as claimed in claim 1, wherein the gate electrode surrounds upper and side surfaces of the first part of the active region.

10. A transistor, comprising:
an active region, the active region including a first part, a second part, and a third part, the second part and the third part facing each other with the first part interposed therebetween;
a gate electrode overlapping the first part of the active region;
a gate dielectric between the gate electrode and the active region;
a drain region in the second part of the active region;
a source region in the third part of the active region; and
a channel region in the first part of the active region,
wherein the channel region includes a first channel region and a second channel region, the second channel region having a channel width greater than the first channel region, and
the second channel region is closer to the drain region than the first channel region.

11. The transistor as claimed in claim 10, wherein the source region has a shallower junction structure than the drain region.

12. The transistor as claimed in claim 1, wherein:
the drain region includes a first drain region and a second drain region, the second drain region having side and bottom surfaces surrounded by the first drain region, and
the second drain region has a higher impurity concentration than the first drain region.

13. The transistor as claimed in claim 12, further comprising an isolation region between the first part and the second part of the active region, wherein the first drain region:
surrounds side and bottom surfaces of the isolation region, and
extends into a portion of the first part of the active region.

14. The transistor as claimed in claim 10, further comprising a channel impurity area, the channel impurity area:
surrounding side and bottom surfaces of the source region, and
being spaced apart from the drain region.

15. The transistor as claimed in claim 10, further comprising an isolation region, the isolation region including:
a portion interposed between the first part and the second pan of the active region, and
a portion interposed between the first part and the third part of the active region,
wherein the drain region:
surrounds side and bottom surfaces of the isolation region that are located between the first part and the second part of the active region, and
extends into a portion of the first part of the active region, and wherein the source region:
surrounds side and bottom surfaces of the isolation region located between the first part and the third part of the active region, and
extends into a portion of the first part of the active region.

16. A semiconductor device, comprising:
an active region;
a gate electrode on the active region; and
a gate dielectric between the gate electrode and the active region,
wherein:
the active region includes a first part overlapped by the gate electrode, a second part at one side of the first pan, and a third part at another side of the first part such that the first part is between the second part and the third part, and
the first part of the active region has a stepped shape including at least one discontinuous change in width therein.

17. The semiconductor device as claimed in claim 16, wherein the second part of the active region includes a portion having a same width as one portion of the first part of the active region.

18. The semiconductor device as claimed in claim 17, wherein the third part of the active region includes a portion having the same width as another portion of the first part of the active region.

19. The semiconductor device as claimed in claim 16, wherein at least one of the second part or the third part has a stepped shape including at least one discontinuous change in width therein.

20. The semiconductor device as claimed in claim 16, wherein the gate electrode surrounds upper and side surfaces of the first part of the active region.
